(19) United States
(12) Patent Application Publication
(10) Pub. No.: US 2015/0333201 A1
(43) Pub. Date: Nov. 19, 2015

(54) PHOTOVOLTAIC DEVICES WITH PLASMONIC NANOPARTICLES

(71) Applicant: THE GOVERNING COUNCIL OF THE UNIVERSITY OF TORONTO, Toronto (CA)

(72) Inventors: Edward H. Sargent, Toronto (CA); Susanna Mitrani Thon, Baltimore, MD (US); Anna Lee, Westmount, IL (US); Daniel Paz-Soldan, Stouffville (CA)

(73) Assignee: THE GOVERNING COUNCIL OF THE UNIVERSITY OF TORONTO, Toronto (CA)

(21) Appl. No.: 14/808,943

(22) Filed: Jul. 24, 2015

Related U.S. Application Data
(63) Continuation of application No. PCT/US2014/017793, filed on Feb. 21, 2014.
(60) Provisional application No. 61/767,394, filed on Feb. 21, 2013.

(51) Int. Cl. H01L 31/0352; H01L 31/0725; H01L 31/073; H01L 31/0224; H01L 31/0749

(52) U.S. Cl. CPC H01L 31/035218; H01L 31/022466; H01L 31/022475; H01L 31/022483; H01L 31/0749; H01L 31/073; H01L 31/0725; B82Y 20/00

(57) ABSTRACT

This application describes photovoltaic devices that include, in some embodiments, plasmonic nanoparticles and colloidal quantum dots and that have enhanced photovoltaic conversion efficiencies. This application also describes methods of making and using photovoltaic devices. Certain photovoltaic devices include plasmonic nanoparticles integrated with light absorbing semiconductor nanoparticles such as, but not limited to, colloidal quantum dots. Certain photovoltaic devices include solution-processed materials (e.g., colloidal plasmonic and light absorbing semiconductor nanoparticles) that are specifically tuned to enhance overall photovoltaic performance through increased absorbance of the light absorbing material.

### CROSS-REFERENCES TO RELATED APPLICATIONS

This application is a continuation of Int'l Application No. PCT/US2014/017793, filed Feb. 21, 2014, which claims priority to U.S. Provisional Patent Application No. 61/767,394, filed Feb. 21, 2013, the entire disclosures of which are herein incorporated by reference in their entirety for all purposes.

### FIELD OF THE INVENTION

The disclosure herein relates to nanoparticles and nanomaterials and their use in photovoltaic devices and related applications.

### BACKGROUND OF THE INVENTION

Solar cells that can efficiently harvest the sun's energy are currently needed in the field of renewable energy. Recent advances in spectrally-tuned, solution-processed plasmonic nanoparticles have provided control over light via engineering at the nanoscale. Colloidal quantum dot (QCD) solar cells use photovoltaic nanoparticles or quantum dots to convert light into electricity and offer a pathway to very high efficiencies. However, to date, CQD solar cells have poor quantum efficiency in the more weakly-absorbed infrared portion of the sun's spectrum.

Plasmonic nanoparticles are known in the art to increase light absorption in various materials such as semiconductors and organic molecules through near-field effects (Brown, M., et al., J. Nano Lett. 2011, 11, 438-445; Hägglund, C., et. al., B. Appl. Phys. Lett. 2008, 92, 013113; Thomann, I., et. al., Nano Lett. 2011, 11, 3440-3446; Rand, B. P.; et. al., J. Appl. Phys. 2004, 96, 7519-7526; Yang, J., et. al., ACS Nano 2011), path-length increases via far-field scattering (Catchpole, K. R.; et. al., Opt. Express 2008, 16, 21793-800; Nakayama, K, et. al., Appl. Phys. Lett. 2008, 93, 121904; Arquer, F. P. G. De, et. al., Appl. Phys. Lett. 2012, 100) and surface plasmon polariton waveguiding (Ferry, V. E.; et. al., A. Nano Lett. 2011, 11, 4239-4245; Ding, I.-K., et. al., Adv. Energy Mater. 2011, 1, 52-57; Li, X., et. al., Adv. Mater. 2012, 24, 3046-52.). While there have been investigations into using plasmonic nanoparticles to enhance solar cell absorption, generally, little work has been done on how they can be used to improve the performance of quantum dot cells. Quantum dot solar cells can be tuned as a function of their size to absorb the sun's power that lies in the infrared. Compositions and methods for enhancing the performance of quantum dot solar cells (e.g., IR-absorbing quantum dot-based solar cells) are urgently needed.

Surprisingly, the devices and materials described herein solve many of the challenges outlined above as well as others known in the art.

### BRIEF SUMMARY OF THE INVENTION

In a first aspect, the present application describes an enhanced infrared (IR) light absorbing photovoltaic stack including a top electrode, an absorbing layer (AL) including light-absorbing semiconductor nanoparticles (SNPs) that absorb at least a portion of the infrared spectrum and at least one plasmonic nanoparticle (PNP), and a bottom electrode, wherein the PNP scatters incident IR light and thereby enhances IR absorption by the SNPs.

In a second aspect, this application describes a composition including infrared absorbing semiconductor nanoparticles (SNPs) and at least one plasmonic nanoparticle (PNP), wherein the composition contacts an electrode.

In a third aspect, this application describes an enhanced absorbing medium (EAM) including SNPs embedded with at least one PNP, wherein the SNPs include infrared absorbing PbS quantum dots, and wherein the PNP includes: a spherical dielectric core having an average diameter of about 25 nm to about 100 nm, a metal shell surrounding the core and having an average thickness of about 2 nm to 50 nm, and, optionally an insulating shell surrounding the metal shell.

In a fourth aspect, this application describes a light emitting colloid including colloidal SNPs and at least one PNP, wherein the SNPs includes infrared absorbing quantum dots, and wherein the PNP includes: a spherical dielectric core having an average diameter of about 25 nm to about 100 nm, a metal shell surrounding the core, having an average thickness of about 2 nm to 50 nm, and, optionally an insulating shell surrounding the metal shell.

In a fifth aspect, this application describes a method of preparing a photovoltaic device, including providing a bottom electrode selected from the group consisting of fluorine-doped tin oxide (FTO), indium-tin-oxide (ITO), TiO₂—FTO. ZnO—TiO₂—FTO. TiO₂—ITO, and ZnO—TiO₂—ITO, drop-casting SNPs to form a first AL on the bottom electrode, drop-casting at least one PNP onto the AL, drop-casting SNPs onto the at least one PNP and first AL to form a second AL thereupon, and depositing a top electrode onto the second AL, thereby preparing the photovoltaic device.

In a sixth aspect, this application describes a method of generating electricity or converting light into electricity, including illuminating a photovoltaic device described herein with infrared light.

### BRIEF DESCRIPTION OF THE DRAWINGS

FIG. 1 shows the characteristics of plasmonic nanoparticle compositions.

FIG. 2 shows an example of a three dimensional full-wave finite-difference time-domain (FDTD) simulation of combined plasmonic and colloidal quantum dot (plasmonic-excitonic) films.

FIG. 3 shows a plasmonic-excitonic solar cell device design.

FIG. 4 shows the performance of a photovoltaic device incorporating plasmonic and CQD nanoparticles.

FIG. 5 shows the UV-Vis-NIR absorption and scattering spectra taken in an integrating sphere for a drop-cast ensemble of (a) nanorods and (b) nanoshells on an ITO-coated glass substrate.

FIG. 6 shows various full-wave finite-difference time-domain (FDTD) simulations of the characteristics of photovoltaic devices that include plasmonic nanoparticles.

FIG. 7 shows examples of electric field intensity profiles with various embodiments of plasmonic nanoparticle placement.

FIG. 8 shows examples of absorption profiles for unenhanced and plasmonically enhanced photovoltaic films.

FIG. 9 shows cross-sectional TEM image and elemental distributions for a photovoltaic film incorporating plasmonic and light absorbing semiconductor nanoparticles.

FIG. 10 shows various full-wave finite-difference time-domain (FDTD) simulations predicting the scattering characteristics of plasmonic nanoparticles.

FIG. 11 shows various full-wave finite-difference time-domain (FDTD) simulations of the absorption in a light absorbing semiconductor nanoparticle film within a photovoltaic device.

### DETAILED DESCRIPTION

### Definitions

As used herein, the term “photovoltaic” refers to a semiconductor that absorbs light energy and converts this light energy into electrical energy, e.g. photo-generated electrons and photo-generated holes that flow to separate electrical contacts and are capable of transferring energy to an electrical load.

As used herein, the term “semiconductor” refers to a material in which the Fermi-level, i.e. the work function, is between the conduction band and the valence band. Examples of semiconductors include bulk materials, e.g., TiO₂ and ZnO, as well as nanomaterials, e.g., CdS quantum dots.

As used herein, the term “enhanced,” refers to the improved performance observed for a material, photovoltaic, or related device. In some instances, the light (e.g., IR) that is scattered by plasmonic nanoparticles can be absorbed by the SNPs. Since this scattered light would otherwise be lost, and unusable for photocurrent generation, the absorption of this scattered light enhances, or improves, the total amount of light that the SNPs can absorb. In certain instances, light absorption can be enhanced due to near-field effects wherein the plasmonic nanoparticles lead to an intensified optical field in the light-absorbing semiconductor, thereby improving the total amount of light that the SNPs can absorb.

As used herein, the term “scattering,” refers to a physical process where light is forced away from a straight trajectory by one or more paths due to localized non-uniformities in the medium through which they pass. For example, the plasmonic particles described herein may scatter IR light, that would otherwise be lost from the solar cell device, and direct this IR light to a quantum-dot for absorption and use in generating a photocurrent.

As used herein, the term “absorption,” refers to the process whereby a material incorporates the energy associated with a photon. “Absorption” also refers to the process whereby a material facilitates the conversion of light energy (i.e., the energy of a photon) into electrical energy. When a CQD solar cell is illuminated and generates a photocurrent, the quantum dots absorb the energy of photons and convert this energy into electricity.

As used herein, the term “the plasmonic nanoparticle” refers to a colloidal particle having nanosized dimensions. In some instances, the nanoparticle has a core made from an insulator and a shell made out of a metal. In some instances, the nanoparticle has a scattering-to-absorption ratio greater than 1. Examples of metals include in these nanoparticles are gold and silver.

As used herein, the term “bandgap excitation wavelength,” refers to the wavelength of light required to excite an electron from the valence band to the conduction band in a bandgap material.

As used herein, the term “stack,” refers to one or more photovoltaic junctions in series (i.e., electrical contact).

As used herein, the term “at least a portion of the IR spectrum,” refers to a portion of the sun's spectrum typically in the range 700 nm to 1800 nm. An example range of interest suitable for use herein, for enhancement, includes, but is not limited to, 700-1000 nm, which in a single-junction solar cell requires high absorption and thus benefits typically from absorption enhancement. Another example range suitable for use herein, for enhancement, includes but is not limited to 700-1300 nm, which in a tandem solar cell requires high absorption in the back (smaller-bandgap) cell.

As used herein the term “top,” refers the side of the photovoltaic device that is the illuminated surface when the photovoltaic is used to generate a photocurrent.

As used herein, the term “bottom,” refers to the side of the device opposite the top. In some examples, the bottom is directly opposite the top.

As used herein, the term “core-shell nanoparticles,” refers to nanoparticles that include a core, or centrally located, material that is surrounded by another distinct material and wherein the other material surrounds the core material in a shell geometry.

As used herein, the term “about” when used with a numerical value, includes a range that is plus or minus at least 15% or less of that value. For example, about 2 nm includes 2.3 nm and 1.7 nm as well as the values therebetween, such as 1.8 nm, 1.9 nm, 2.1, and 2.2 nm. For example, about 10 nm includes 8.5 nm, 9.0 nm, 9.5 nm, 10 nm, and 10.5 nm as well as the values therebetween.

As used herein, the phrase “about the same size,” refers to sizes of nanoparticles that do not differ in size by more than one standard deviation or less. In some instances, about the same sizes may include particles that have the same size plus or minus 15% of that size. For example, a nanoparticle that is 9.5 nm is diameter is about the same size as a nanoparticle that is 10 nm in diameter.

As used herein, the term “depleted heterojunction” refers to a photovoltaic junction that is substantially depleted of both free electrons and free holes on at least one side of the junction when the device is not illuminated. The term “substantially depleted” as used herein to characterize the region(s) adjacent to a heterojunction denotes that the charge density in the region(s) is orders of magnitude less than that of the metal side of a Schottky junction. In certain heterojunction regions of the invention, the charge density is three or more orders of magnitude less than the charge density of conducting metals, and in many of these, the charge density is four or more, five or more, or six or more orders of magnitude less. Particularly effective results can be achieved when the depleted charge density is on the n-type electron accepting layer side of the junction. In many embodiments of the invention, a range of charge density in the depleted region is about 1×10¹² cm⁻³ to about 1×10¹⁸ cm⁻³, or alternatively about 1×10¹⁴ cm⁻³ to about 1×10¹⁷ cm⁻³, or as a further alternative about 1×10¹⁵ cm⁻³ to about 1×10¹⁶ cm⁻³. Examples of depleted heterojunctions include, but are not limited to, those depleted heterojunctions set forth in International Patent Application Publication No. WO 2011/126778 (Tang, Jiang, et al.), published on Oct. 13, 2011.

To achieve a depleted heterojunction by use of materials of different bandgap magnitudes on the two sides of the junction, effective results in many cases can be achieved with a bandgap difference (i.e., the difference between the bandgap magnitude on one side of the junction and the bandgap magnitude on the other side of the junction) of at least about 0.25 eV. 0.5 eV, 1.0 eV, 1.5 eV, or within the range of from about 1.5 eV to about 5 eV, or even more effectively within the range of from about 2 eV to about 5 eV.

As used herein, the term “nanoparticle” refers to a composition of matter with physical dimensions on the order of nanometers. For example, a spherical nanoparticle has a diameter that can range from about one nanometer to about one hundred nanometers. A spherical nanoparticle has a diameter that can range from about one nanometer to about fifty nanometers. In some embodiments, a spherical nanoparticle has a diameter that can range from about one nanometer to about twenty five nanometers. Example nanoparticles include, but are not limited to: metal nanoparticles, e.g. Cu, Au, Ag, Ni, Pd, and Pt: binary nanoparticles, e.g. PbS, CdS, and CdSe quantum dots, or core-shell quantum dots: metal oxides nanoparticles, e.g. ZnO, TiO₂, and organic nanoparticles, e.g. carbon nanotubes, fullerenes, organic aggregates, and micelles.

As used herein, the term “thickness” refers to the width or physical dimension of the object qualified by the word thickness.

Photovoltaic Devices

In some embodiments, the present application describes an enhanced infrared (IR) light absorbing photovoltaic stack. The stack includes a top electrode; an absorbing layer (AL) including light-absorbing semiconductor nanoparticles (SNPs). The stacks also includes at least one plasmonic nanoparticle (PNP) and a bottom electrode. The PNP scatters incident IR light and thereby enhances IR absorption by the SNPs.

In some of the above embodiments, the SNPs absorb at least a portion of the infrared spectrum. Some of the SNPs described herein absorb at least a portion of the IR spectrum absorb light between about 700 nm to 1800 nm. Some other SNPs set forth herein absorb at least a portion of the IR spectrum absorb light between about 700 to about 1000 nm. Certain other SNPs that absorb at least a portion of the IR spectrum absorb light between about 700 to about 1300 nm.

In certain of the above embodiments, the AL is between and contacts the top electrode and the bottom electrode. In some embodiments, the top electrode is selected from the group consisting of Au, Ag, Pt. Pd, Ni, MoO₃, and combinations thereof. In certain embodiments, the top electrode is Au. In certain other embodiments, the top electrode is Ag. In other embodiments, the top electrode is Pt. In some embodiments, the top electrode is Pd. In certain embodiments, the top electrode is Ni. In certain other embodiments, the top electrode is MoO₃. In certain embodiments, the top electrode is a combination of Au. Ag, Pt, Pd, Ni, and MoO₃.

In certain embodiments, the SNPs are selected from the group consisting of PbS, PbSe, CdS, CdSe, CdTe, PbTe, ZnS, ZnTe, ZnSe, and core-shell nanoparticles. In some, the SNPs are PbS. In others, the SNPs are PbSe. In some others, the SNPs are CdS. In yet others, the SNPs are CdSe. In others, the SNPs are CdTe. In still others, the SNPs are PbTe. In still others, the SNPs are ZnS. In still others, the SNPs are ZnTe. In still others, the SNPs are ZnSe. In other embodiments, the SNPs are combinations of PbS, PbSe, CdS, CdSe, CdTe, PbTe, ZnS, ZnTe, ZnSe, and core-shell nanoparticles.

In some embodiments, the SNPs absorb IR light. In some other embodiments, the SNPs absorb at least a portion of the IR spectrum.

In certain of the above embodiments, the SNPs include PbS colloidal quantum dots having a diameter from about 2 nm to about 10 nm. In some instances, the diameter is 2 nm, 3 nm, 4 nm, 5 nm, 6 nm, 7 nm, 8 nm, 9 nm, or 10 nm. In some of these embodiments, the diameter is 2 nm. In some of these embodiments, the diameter is 3 nm. In some of these embodiments, the diameter is 4 nm. In some of these embodiments, the diameter is 5 nm. In some of these embodiments, the diameter is 6 nm. In some of these embodiments, the diameter is 8 nm. In some of these embodiments, the diameter is 9 nm. In some of these embodiments, the diameter is 10 nm. In some embodiments, the SNPs include diameters that include more than one size selected from 2 nm, 3 nm, 4 nm, 5 nm, 6 nm, 7 nm, 8 nm. 9 nm, or 10 nm.

In certain of the above embodiments, wherein the SNPs include PbS colloidal quantum dots having about the same sizes.

In certain of the above embodiments, halide ions are bonded to the quantum dot's surface. In some embodiments, the halide ions are selected from the group consisting of fluoride, bromide, chloride, iodide, and combinations thereof. In some of these, the halide is F. In others, the halide is Br. In yet others, the halide is Cl. In some others, the halide is I.

In certain of the above embodiments, the PNP includes a spherical dielectric core having an average diameter of about 25 nm to about 100 nm; a metal shell surrounding the core and having an average thickness of about 2 nm to 50 nm; and, optionally an insulating shell surrounding the metal shell having an average thickness of about 2 nm to 50 nm.

In some embodiments, the insulating shell surrounding the metal shell has an average thickness of about 2 nm to 50 nm, or about 2 to 48 nm, or about 2 to 46 nm, or about 2 to 44 nm, or about 2 to 40 nm, or about 2 to 38 nm, or about 2 to 36 nm, or about 2 to 34 nm.

In some embodiments, the spherical dielectric core has an average diameter of about 25 nm to about 100 nm, or about 35 to about 100 nm, or about 45 to about 100 nm, or about 55 to about 100 nm, or about 65 to about 100 nm. In some embodiments, the spherical dielectric core has an average diameter of about 25 nm to about 750 nm, or about 35 to about 85 nm, or about 45 to about 65 nm, or about 55 to about 75 nm, or about 65 to about 90 nm.

In some embodiments, the spherical dielectric core has an average diameter of 25 nm to 100 nm, or 35 to 100 nm, or 45 to 100 nm, or 55 to 100 nm, or 65 to 100 nm. In some embodiments, the spherical dielectric core has an average diameter of 25 nm to 750 nm, or 35 to 85 nm, or 45 to 65 nm, or 55 to 75 nm, or 65 to 90 nm.

In some embodiments, the application describes a metal shell surrounding the core and having an average thickness of about 2 nm to 50 nm; and, optionally an insulating shell surrounding the metal shell having an average thickness of about 2 nm to 50 nm. In some embodiments, the metal shell has a thickness of 4 nm. In some embodiments, the metal shell has a thickness of 6 nm. In some embodiments, the metal shell has a thickness of 8 nm. In some embodiments, the metal shell has a thickness of 10 nm. In some embodiments, the metal shell has a thickness of 12 nm. In some embodiments, the metal shell has a thickness of 14 nm. In some embodiments, the metal shell has a thickness of 16 nm. In some embodiments, the metal shell has a thickness of 18 nm. In some embodiments, the metal shell has a thickness of 20 nm. In some embodiments, the metal shell has a thickness of 22 nm In some embodiments, the metal shell has a thickness of 24 nm. In some embodiments, the metal shell has a thickness of 26 nm. In some embodiments, the metal shell has a thickness of 28 nm. In some embodiments, the metal shell has a thickness of 30 nm. In some embodiments, the metal shell has a thickness of 32 nm. In some embodiments, the metal shell has a thickness of 34 nm. In some embodiments, the metal shell has a thickness of 36 nm. In some embodiments, the metal shell has a thickness of 38 nm. In some embodiments, the metal shell has a thickness of 40 nm. In some embodiments, the metal shell has a thickness of 42 nm. In some embodiments, the metal shell has a thickness of 44 nm. In some embodiments, the metal shell has a thickness of 46 nm. In some embodiments, the metal shell has a thickness of 48 nm. In some embodiments, the metal shell has a thickness of 50 nm.

In some embodiments, the application describes a metal shell surrounding the core and having an average thickness of about 2 nm to 50 nm. In some other embodiment, the application describes a metal shell surrounding the core and having an average thickness of about 4 nm to 50 nm. In yet other embodiments, the application describes a metal shell surrounding the core and having an average thickness of about 6 nm to 50 nm. In some embodiments, the application describes a metal shell surrounding the core and having an average thickness of about 8 nm to 50 nm. In some other embodiments, the application describes a metal shell surrounding the core and having an average thickness of about 10 nm to 50 nm. In some embodiments, the application describes a metal shell surrounding the core and having an average thickness of about 12 nm to 50 nm. In some other embodiment, the application describes a metal shell surrounding the core and having an average thickness of about 14 nm to 50 nm. In yet other embodiments, the application describes a metal shell surrounding the core and having an average thickness of about 16 nm to 50 nm. In some embodiments, the application describes a metal shell surrounding the core and having an average thickness of about 18 nm to 50 nm. In some other embodiments, the application describes a metal shell surrounding the core and having an average thickness of about 20 nm to 50 nm. In some embodiments, the application describes a metal shell surrounding the core and having an average thickness of about 22 nm to 50 nm. In some other embodiment, the application describes a metal shell surrounding the core and having an average thickness of about 24 nm to 50 nm. In yet other embodiments, the application describes a metal shell surrounding the core and having an average thickness of about 26 nm to 50 nm. In some embodiments, the application describes a metal shell surrounding the core and having an average thickness of about 28 nm to 50 nm. In some other embodiments, the application describes a metal shell surrounding the core and having an average thickness of about 30 nm to 50 nm. In some embodiments, the application describes a metal shell surrounding the core and having an average thickness of about 32 nm to 50 nm. In some other embodiment, the application describes a metal shell surrounding the core and having an average thickness of about 34 nm to 50 nm. In yet other embodiments, the application describes a metal shell surrounding the core and having an average thickness of about 36 nm to 50 nm. In some embodiments, the application describes a metal shell surrounding the core and having an average thickness of about 38 nm to 50 nm. In some other embodiments, the application describes a metal shell surrounding the core and having an average thickness of about 40 nm to 50 nm.

In some embodiments, the application describes a metal shell surrounding the core and having an average thickness of about 2 nm to 48 nm. In some other embodiment, the application describes a metal shell surrounding the core and having an average thickness of about 2 nm to 46 nm. In yet other embodiments, the application describes a metal shell surrounding the core and having an average thickness of about 2 nm to 44 nm. In some embodiments, the application describes a metal shell surrounding the core and having an average thickness of about 2 nm to 42 nm. In some other embodiments, the application describes a metal shell surrounding the core and having an average thickness of about 2 nm to 40 nm. In some embodiments, the application describes a metal shell surrounding the core and having an average thickness of about 2 nm to 38 nm. In some other embodiment, the application describes a metal shell surrounding the core and having an average thickness of about 2 nm to 36 nm. In yet other embodiments, the application describes a metal shell surrounding the core and having an average thickness of about 2 nm to 34 nm. In some embodiments, the application describes a metal shell surrounding the core and having an average thickness of about 2 nm to 32 nm. In some other embodiments, the application describes a metal shell surrounding the core and having an average thickness of about 2 nm to 30 nm. In some embodiments, the application describes a metal shell surrounding the core and having an average thickness of about 2 nm to 28 nm. In some other embodiment, the application describes a metal shell surrounding the core and having an average thickness of about 2 nm to 26 nm. In yet other embodiments, the application describes a metal shell surrounding the core and having an average thickness of about 2 nm to 24 nm. In some embodiments, the application describes a metal shell surrounding the core and having an average thickness of about 2 nm to 22 nm. In some other embodiments, the application describes a metal shell surrounding the core and having an average thickness of about 2 nm to 20 nm. In some embodiments, the application describes a metal shell surrounding the core and having an average thickness of about 2 nm to 18 nm. In some other embodiment, the application describes a metal shell surrounding the core and having an average thickness of about 2 nm to 16 nm. In yet other embodiments, the application describes a metal shell surrounding the core and having an average thickness of about 2 nm to 14 nm. In some embodiments, the application describes a metal shell surrounding the core and having an average thickness of about 2 nm to 12 nm. In some other embodiments, the application describes a metal shell surrounding the core and having an average thickness of about 2 nm to 10 nm.

In some embodiments, the application describes a metal shell surrounding the core and having an average thickness of about 2 nm to 48 nm. In some other embodiment, the application describes a metal shell surrounding the core and having an average thickness of about 4 nm to 46 nm. In yet other embodiments, the application describes a metal shell surrounding the core and having an average thickness of about 6 nm to 44 nm. In some embodiments, the application describes a metal shell surrounding the core and having an average thickness of about 8 nm to 42 nm. In some other embodiments, the application describes a metal shell surrounding the core and having an average thickness of about 10 nm to 40 nm. In some embodiments, the application describes a metal shell surrounding the core and having an average thickness of about 12 nm to 38 nm. In some other embodiment, the application describes a metal shell surrounding the core and having an average thickness of about 14 nm to 36 nm. In yet other embodiments, the application describes a metal shell surrounding the core and having an average thickness of about 16 nm to 34 nm. In some embodiments, the application describes a metal shell surrounding the core and having an average thickness of about 18 nm to 32 nm. In some other embodiments, the application describes a metal shell surrounding the core and having an average thickness of about 20 nm to 30 nm. In some embodiments, the application describes a metal shell surrounding the core and having an average thickness of about 22 nm to 28 nm. In some other embodiment, the application describes a metal shell surrounding the core and having an average thickness of about 24 nm to 26 nm.

In some embodiments, the application describes an insulating shell having an average thickness of about 2 nm to 50 nm. In some other embodiment, the application describes an insulating shell having an average thickness of about 4 nm to 50 nm. In yet other embodiments, the application describes an insulating shell having an average thickness of about 6 nm to 50 nm. In some embodiments, the application describes an insulating shell having an average thickness of about 8 nm to 50 nm. In some other embodiments, the application describes an insulating shell having an average thickness of about 10 nm to 50 nm. In some embodiments, the application describes an insulating shell having an average thickness of about 12 nm to 50 nm. In some other embodiment, the application describes an insulating shell having an average thickness of about 14 nm to 50 nm. In yet other embodiments, the application describes an insulating having an average thickness of about 16 nm to 50 nm. In some embodiments, the application describes an insulating shell having an average thickness of about 18 nm to 50 nm. In some other embodiments, the application describes an insulating shell having an average thickness of about 20 nm to 50 nm. In some embodiments, the application describes an insulating shell having an average thickness of about 22 nm to 50 nm. In some other embodiment, the application describes an insulating shell having an average thickness of about 24 nm to 50 nm. In yet other embodiments, the application describes an insulating shell having an average thickness of about 26 nm to 50 nm. In some embodiments, the application describes an insulating shell having an average thickness of about 28 nm to 50 nm. In some other embodiments, the application describes an insulating shell having an average thickness of about 30 nm to 50 nm. In some embodiments, the application describes an insulating shell having an average thickness of about 32 nm to 50 nm. In some other embodiment, the application describes a metal shell surrounding the core and having an average thickness of about 34 nm to 50 nm. In yet other embodiments, the application describes an insulating shell having an average thickness of about 36 nm to 50 nm. In some embodiments, the application describes an insulating shell having an average thickness of about 38 nm to 50 nm. In some other embodiments, the application describes an insulating shell having an average thickness of about 40 nm to 50 nm.

In some embodiments, the application describes an insulating shell having an average thickness of about 2 nm to 48 nm. In some other embodiment, the application describes an insulating shell having an average thickness of about 2 nm to 46 nm. In yet other embodiments, the application describes an insulating shell having an average thickness of about 2 nm to 44 nm. In some embodiments, the application describes an insulating shell having an average thickness of about 2 nm to 42 nm. In some other embodiments, the application describes an insulating shell having an average thickness of about 2 nm to 40 nm. In some embodiments, the application describes an insulating shell having an average thickness of about 2 nm to 38 nm. In some other embodiment, the application describes an insulating shell having an average thickness of about 2 nm to 36 nm. In yet other embodiments, the application describes an insulating shell having an average thickness of about 2 nm to 34 nm. In some embodiments, the application describes an insulating shell having an average thickness of about 2 nm to 32 nm. In some other embodiments, the application describes an insulating shell having an average thickness of about 2 nm to 30 nm. In some embodiments, the application describes an insulating shell having an average thickness of about 2 nm to 28 nm. In some other embodiment, the application describes an insulating shell having an average thickness of about 2 nm to 26 nm. In yet other embodiments, the application describes an insulating shell having an average thickness of about 2 nm to 24 nm. In some embodiments, the application describes an insulating shell having an average thickness of about 2 nm to 22 nm. In some other embodiments, the application describes an insulating shell having an average thickness of about 2 nm to 20 nm. In some embodiments, the application describes an insulating shell having an average thickness of about 2 nm to 18 nm. In some other embodiment, the application describes an insulating shell having an average thickness of about 2 nm to 16 nm. In yet other embodiments, the application describes an insulating shell having an average thickness of about 2 nm to 14 nm. In some embodiments, the application describes an insulating shell having an average thickness of about 2 nm to 12 nm. In some other embodiments, the application an insulating shell having an average thickness of about 2 nm to 10 nm.

In some embodiments, the application describes an insulating shell having an average thickness of about 2 nm to 48 nm. In some other embodiment, the application describes an insulating shell having an average thickness of about 4 nm to 46 nm. In yet other embodiments, the application describes an insulating shell having an average thickness of about 6 nm to 44 nm. In some embodiments, the application describes an insulating shell having an average thickness of about 8 nm to 42 nm. In some other embodiments, the application an insulating shell having an average thickness of about 10 nm to 40 nm. In some embodiments, the application describes an insulating shell having an average thickness of about 12 nm to 38 nm. In some other embodiment, the application describes an insulating shell having an average thickness of about 14 nm to 36 nm. In yet other embodiments, the application describes an insulating shell having an average thickness of about 16 nm to 34 nm. In some embodiments, the application describes an insulating shell having an average thickness of about 18 nm to 32 nm. In some other embodiments, the application describes an insulating shell having an average thickness of about 20 nm to 30 nm. In some embodiments, the application describes an insulating shell having an average thickness of about 22 nm to 28 nm. In some other embodiment, the application describes an insulating shell having an average thickness of about 24 nm to 26 nm.

In certain of the above embodiments, the dielectric core is selected from SiO₂, Si₃N₄, polystyrene, insulating polymers, and insulating metal oxides. In certain of the above embodiments, the metal is selected from Cu, Ag, Au, Pt, Pd, Ni, Al, or combinations thereof. In certain of the above embodiments, the core is SiO₂, the metal shell is Au, and the insulating shell is polyvinylpyrrolidone (PVP). In other embodiments, the core is SiO₂ and has a diameter of about 60 nm; and wherein the metal shell is Au and has a thickness of about 15 nm. In other embodiments, the core has an average diameter of about 120 nm and the metal shell has an average thickness of about 15 nm. In others, the core has an average diameter of about 50 nm and the metal shell has an average thickness of about 15 nm. In some other embodiments, the PNP has an average diameter of about 50 nm to about 80 nm.

In certain embodiments, the PNP has an average diameter of about 50 nm. In some embodiments, the PNP has an average diameter of about 52 nm. In certain other embodiments, the PNP has an average diameter of about 54 nm. In yet other embodiments, the PNP has an average diameter of about 55 nm. In certain embodiments, the PNP has an average diameter of about 57 nm. In some embodiments, the PNP has an average diameter of about 58 nm. In certain other embodiments, the PNP has an average diameter of about 59 nm. In yet other embodiments, the PNP has an average diameter of about 60 nm. In certain embodiments, the PNP has an average diameter of about 62 nm. In some embodiments, the PNP has an average diameter of about 64 nm. In certain other embodiments, the PNP has an average diameter of about 65 nm. In yet other embodiments, the PNP has an average diameter of about 67 nm. In certain embodiments, the PNP has an average diameter of about 69 nm. In some embodiments, the PNP has an average diameter of about 70 nm. In certain other embodiments, the PNP has an average diameter of about 71 nm. In yet other embodiments, the PNP has an average diameter of about 72 nm. In still others, the PNP has an average diameter of about 75 nm.

In certain embodiments, the PNP has an average diameter of 50 nm. In some embodiments, the PNP has an average diameter of 52 nm. In certain other embodiments, the PNP has an average diameter of 54 nm. In yet other embodiments, the PNP has an average diameter of 55 nm. In certain embodiments, the PNP has an average diameter of 57 nm. In some embodiments, the PNP has an average diameter of 58 nm. In certain other embodiments, the PNP has an average diameter of 59 nm. In yet other embodiments, the PNP has an average diameter of 60 nm. In certain embodiments, the PNP has an average diameter of 62 nm. In some embodiments, the PNP has an average diameter of 64 nm. In certain other embodiments, the PNP has an average diameter of 65 nm. In yet other embodiments, the PNP has an average diameter of 67 nm. In certain embodiments, the PNP has an average diameter of 69 nm. In some embodiments, the PNP has an average diameter of 70 nm. In certain other embodiments, the PNP has an average diameter of 71 nm. In yet other embodiments, the PNP has an average diameter of 72 nm. In still others, the PNP has an average diameter of 75 nm.

In other embodiments, the PNP is selected from the group consisting of the PNP set forth here, nanorods having an average diameter of about 50 nm to about 70 nm and an average length of about 450 nm to about 550 nm, and nanospheres having an average diameter of about 100 nm to about 200 nm.

In some embodiments described herein, the PNP is a nanorod or a nanosphere and includes a metal selected from the group consisting of Cu, Ag, Au, Pt, and combinations thereof.

In certain embodiments, the metal is Cu. In certain other embodiments, the metal is Ag. In certain embodiments, the metal is Au. In certain embodiments, the metal is Pt.

In some embodiments described herein, the PNP has an average diameter of about 150 nm or less. In some of these embodiments, the PNP has an average diameter of about 125 nm or less. In some other of these embodiments, the PNP has an average diameter of about 100 nm or less. In some of these embodiments, the PNP has an average diameter of about 90 nm or less.

In certain embodiments described herein, the at least one PNP is positioned about 50% to about 85% of the thickness of the stack from the top electrode. In other embodiments, the at least one PNP is positioned about 55% to about 75% of the thickness of the stack from the top electrode. In other embodiments, the at least one PNP is positioned about 60% to about 75% of the thickness of the stack from the top electrode. In some other embodiments, the at least one PNP is positioned about 55% to about 60% of the thickness of the stack from the top electrode. In other embodiments, the at least one PNP is positioned about 55% to about 70% of the thickness of the stack from the top electrode.

In some of the above embodiments described herein, the at least one PNP is positioned about 60% to about 70% of the thickness of the stack from the top electrode.

In some other embodiments described herein, the at least one PNP is positioned about 65% of the thickness of the stack from the top electrode.

In certain embodiments described herein, the at least one PNP is positioned about 66.6% of the thickness of the stack from the top electrode.

In some embodiments described herein, the at least one PNP is positioned about 10, 20, 30, 40, 50, 60, 70, 80, 90, 100, 110, 120, 130, 140, 150, 160, 170, 180, 190, 200, 210, 220, 230, 240, 250, 260, 270, 280, 290, 300, 310, 320, 330, 340, 350, 360, 370, 380, or 390 nm from the top electrode.

In some embodiments described herein, the at least one PNP is positioned about 100, 150, 200, 250, 300, or 350 nm from the top electrode.

In yet other embodiments described herein, the at least one PNP is positioned about 200, 210, 220, 230, 240, 250, 260, 270, 280, 290, or 300 nm from the top electrode.

In some embodiments described herein, the at least one PNP is positioned about 260 nm from the top electrode.

In certain embodiments described herein, the bottom electrode is selected from the group consisting of fluorine-doped tin oxide (FTO), indium-tin-oxide (ITO), TiO₂/FTO, ZnO/TiO₂/FTO, TiO₂/ITO, ZnO/TiO₂/ITO, and AZO (aluminum-doped Zinc Oxide)/FTO. In some embodiments, the bottom electrode is fluorine-doped tin oxide (FTO). In some embodiments, the bottom electrode is indium-tin-oxide (ITO). In some embodiments, the bottom electrode is TiO₂/FTO. In some embodiments, the bottom electrode is ZnO/TiO₂/FTO. In some embodiments, the bottom electrode is TiO₂/ITO, In some embodiments, the bottom electrode is ZnO/TiO₂/ITO. In some other embodiments, the bottom electrode is AZO (aluminum-doped Zinc Oxide)/FTO.

In certain other embodiments described herein, the bottom electrode includes a depleted heterojunction layer (DHL) that contacts the AL.

In other embodiments described herein, the bottom electrode is transparent to visible light.

In some embodiments described herein, the top electrode is the illuminated surface when the photovoltaic is used to generate a photocurrent.

In some other embodiments described herein, the thickness of the top electrode is about 0.1 nm to about 100 nm.

In yet other embodiments described herein, the thickness of the photovoltaic stack is about 300 nm to about 400 nm. In some embodiments described herein, the thickness of the photovoltaic stack is about 400 nm. In some embodiments described herein, the thickness of the photovoltaic stack is about 250 nm. In some embodiments described herein, the thickness of the photovoltaic stack is about 350 nm. In some embodiments described herein, the thickness of the photovoltaic stack is about 375 nm.

In yet other embodiments described herein, the thickness of the photovoltaic stack is 300 nm to 400 nm. In some embodiments described herein, the thickness of the photovoltaic stack is 400 nm. In some embodiments described herein, the thickness of the photovoltaic stack is 250 nm. In some embodiments described herein, the thickness of the photovoltaic stack is 350 nm. In some embodiments described herein, the thickness of the photovoltaic stack is 375 nm.

In certain embodiments described herein, the thickness of the AL is about 50 nm to about 500 nm. In some other embodiments described herein, the thickness of the AL is about 300 nm to about 400 nm.

In some embodiments described herein, the thickness of (depleted heterojunction layer) DHL is about 5 nm to about 200 nm.

In some of the embodiments set forth herein, the photovoltaic stack has about 2 to about 15 PNPs per μm². In others, the stack has about 10 PNPs per μm².

This application also describes a photovoltaic device that includes a photovoltaic stack described above. In some embodiments, the device includes more than one photovoltaic stack of claim 1.

In some of the photovoltaic devices described herein, the PNP has a scattering-to-absorption ratio, S=σscattering/σabsorption, that is greater than 1 for wavelengths ranging from 400 nm to 1200 nm.

In some of the photovoltaic devices described herein, S is substantially greater than 1.

In some other photovoltaic devices described herein, S is greater than 1.5.

In yet other photovoltaic devices described herein, S is greater than 2.

In some of the photovoltaic devices described herein, S is greater than 3.

In certain photovoltaic stacks or photovoltaic devices described herein, the PNP has a localized surface plasmon resonance (LSPR) centered around a wavelength of 600, 650, 700, 750, 800, 850, 900, 950, or 1000 nm. In some other of the photovoltaic stacks or photovoltaic devices described herein, the PNP has a LSPR centered around 800 nm.

In some of the photovoltaic stacks or photovoltaic devices described herein, the PNP has a LSPR centered around 820 nm.

In some of the photovoltaic stacks or photovoltaic devices described herein, the PNP has a LSPR with a full width at half maximum (FWHM) of 100, 120, 130, 140, 150, 160, 170, 180, 190, 200, 210, 220, 230, 240, 250, 260, 270, 280, 290, 300, 310, 320, 330, 340 or 350 nm.

In some embodiments, the PNP has a LSPR with a full width at half maximum (FWHM) of 100.

In some embodiments, the PNP has a LSPR with a full width at half maximum (FWHM) of 120.

In some embodiments, the PNP has a LSPR with a full width at half maximum (FWHM) of 130.

In some embodiments, the PNP has a LSPR with a full width at half maximum (FWHM) of 140.

In some embodiments, the PNP has a LSPR with a full width at half maximum (FWHM) of 150.

In some embodiments, the PNP has a LSPR with a full width at half maximum (FWHM) of 160.

In some embodiments, the PNP has a LSPR with a full width at half maximum (FWHM) of 170.

In some embodiments, the PNP has a LSPR with a full width at half maximum (FWHM) of 180.

In some embodiments, the PNP has a LSPR with a full width at half maximum (FWHM) of 190.

In some embodiments, the PNP has a LSPR with a full width at half maximum (FWHM) of 200.

In some embodiments, the PNP has a LSPR with a full width at half maximum (FWHM) of 210.

In some embodiments, the PNP has a LSPR with a full width at half maximum (FWHM) of 220.

In some embodiments, the PNP has a LSPR with a full width at half maximum (FWHM) of 230.

In some embodiments, the PNP has a LSPR with a full width at half maximum (FWHM) of 240.

In some embodiments, the PNP has a LSPR with a full width at half maximum (FWHM) of 250.

In some embodiments, the PNP has a LSPR with a full width at half maximum (FWHM) of 260.

In some embodiments, the PNP has a LSPR with a full width at half maximum (FWHM) of 270.

In some embodiments, the PNP has a LSPR with a full width at half maximum (FWHM) of 280.

In some embodiments, the PNP has a LSPR with a full width at half maximum (FWHM) of 290.

In some embodiments, the PNP has a LSPR with a full width at half maximum (FWHM) of 300.

In some embodiments, the PNP has a LSPR with a full width at half maximum (FWHM) of 310.

In some embodiments, the PNP has a LSPR with a full width at half maximum (FWHM) of 320.

In some embodiments, the PNP has a LSPR with a full width at half maximum (FWHM) of 330.

In some embodiments, the PNP has a LSPR with a full width at half maximum (FWHM) of 340.

In some embodiments, the PNP has a LSPR with a full width at half maximum (FWHM) of 350 nm.

In yet other of the photovoltaic stacks or photovoltaic devices described herein, the FWHM is 280 nm.

In certain photovoltaic stacks or photovoltaic devices described herein, the SNP has a bandgap excitation wavelength in the range 700 nm-1.6 um.

This application also describes a composition including infrared absorbing semiconductor nanoparticles (SNPs) and at least one plasmonic nanoparticle (PNP): wherein the composition contacts an electrode.

In some of the compositions set forth herein, the SNPs are selected from infrared absorbing PbS colloidal quantum dots.

In certain the compositions set forth herein, the SNPs include PbS colloidal quantum dots having about the same sizes.

In some other compositions set forth herein, the SNPs include PbS colloidal quantum dots having different sizes.

In some of the compositions set forth herein, halide ions bonded to the quantum dot's surface. In some embodiments, the halide ions are selected from fluoride, bromide, chloride, iodide, or combinations thereof.

In some other of the compositions set forth herein, the PNP include a spherical dielectric core having an average diameter of about 25 nm to about 100 nm; a metal shell surrounding the core and having an average thickness of about 2 nm to 50 nm; and, optionally an insulating shell surrounding the metal shell.

In certain compositions set forth herein, the PNP is positioned about 15% to about 50% of the thickness of the composition from the electrode.

In yet other compositions set forth herein, the at least one PNP is positioned about 30% to about 40% of the thickness of the composition from the electrode.

In some of the compositions set forth herein, the PNP is positioned about 35% of the thickness of the composition from the electrode.

In some other of the compositions set forth herein, the PNP is positioned about 33.3% of the thickness of the composition from the electrode.

In some of the compositions set forth herein, the thickness of the composition is about 100, 200, 300, 400, or 500 nm.

In certain compositions set forth herein, the thickness of the composition is about 400 nm.

In some of the compositions set forth herein, the PNP has an average diameter of about 150 nm or less.

In some other compositions set forth herein, the electrode is selected from fluorine-doped tin oxide (FTO), indium-tin-oxide (ITO), TiO₂/FTO, ZnO/TiO₂/FTO, TiO₂/ITO, or ZnO/TiO₂/ITO.

In some of the compositions set forth herein, the electrode includes a depleted heterojunction that contacts the AL.

In some of the compositions set forth herein, the PNP has a scattering-to-absorption ratio, S=σscattering/σabsorption, that is greater than 1 for wavelengths ranging from 400 nm to 1200 nm.

In other compositions set forth herein, S is substantially greater than 1.

In certain other compositions set forth herein, S is greater than 1.5.

In some of the compositions set forth herein, S is greater than 2.

In some other of the compositions set forth herein, S is greater than 3.

In some of the compositions set forth herein, the composition has about 2 to about 15 PNP(s) per μm². In some of these compositions, the composition has about 10 plasmonic nanoparticles per μm2.

In some of the compositions described herein, the composition has a PNP having a localized surface plasmon resonance (LSPR) centered around a wavelength of 600, 650, 700, 750, 800, 850, 900, 950, or 1000 nm. In some other embodiments, the composition has a PNP having a localized surface plasmon resonance (LSPR) centered around a wavelength of 600. In some other embodiments, the composition has a PNP having a localized surface plasmon resonance (LSPR) centered around a wavelength of 650. In some other embodiments, the composition has a PNP having a localized surface plasmon resonance (LSPR) centered around a wavelength of 700. In some other embodiments, the composition has a PNP having a localized surface plasmon resonance (LSPR) centered around a wavelength of 750. In some other embodiments, the composition has a PNP having a localized surface plasmon resonance (LSPR) centered around a wavelength of 800. In some other embodiments, the composition has a PNP having a localized surface plasmon resonance (LSPR) centered around a wavelength of 850. In some other embodiments, the composition has a PNP having a localized surface plasmon resonance (LSPR) centered around a wavelength of 900. In some other embodiments, the composition has a PNP having a localized surface plasmon resonance (LSPR) centered around a wavelength of 950. In some other embodiments, the composition has a PNP having a localized surface plasmon resonance (LSPR) centered around a wavelength of 1000 nm.

In some of the compositions set forth herein, the PNP has a LSPR centered around 800 nm.

In certain compositions set forth herein, the PNP has a LSPR centered around 820 nm.

In yet other compositions set forth herein, the PNP has a LSPR with a full width at half maximum (FWHM) of 100, 120, 130, 140, 150, 160, 170, 180, 190, 200, 210, 220, 230, 240, 250, 260, 270, 280, 290, 300, 310, 320, 330, 340 or 350 nm. In some of the compositions set forth herein, the FWHM is 280 nm.

In some of the compositions set forth herein, the SNP has a bandgap excitation wavelength of about 980 nm.

Some embodiments described herein include an enhanced absorbing medium (EAM) that includes SNPs embedded with at least one PNP; wherein the SNPs include infrared absorbing PbS quantum dots; and wherein the PNP include a spherical dielectric core having an average diameter of about 25 nm to about 100 nm; a metal shell surrounding the core and having an average thickness of about 2 nm to 50 nm; and, optionally an insulating shell surrounding the metal shell.

In certain of these embodiments, the EAM has a PNP/SNP number-of-particles ratio of about 1:5; 1:10; 1:15: 1:20; 1:25; 1:50: 1:100; 1:250; 1:500; 1:1000; or 1:10,000.

In certain of these embodiments, the EAM has a PNP/SNP number-of-particles ratio is 1:10.000; 1:100.000; 1:1,000,000; or 1:10,000,000. In some of these embodiments, the EAM has a PNP/SNP number-of-particles ratio of 1:10,000. In some of these embodiments, the EAM has a PNP/SNP number-of-particles ratio of 1:100,000. In some of these embodiments, the EAM has a PNP/SNP number-of-particles ratio is 1:10,000,000. In some of these embodiments, the EAM has a PNP/SNP number-of-particles ratio of 1:1.000.000.

This application also describes a light emitting colloid including colloidal SNPs and at least one PNP; wherein the SNPs includes infrared absorbing PbS quantum dots; and wherein the PNP includes a spherical dielectric core having an average diameter of about 25 nm to about 100 nm; a metal shell surrounding the core and having an average thickness of about 2 nm to 50 nm; and, optionally an insulating shell surrounding the metal shell.

This application also describes a method of preparing a photovoltaic including providing a bottom electrode selected from the group consisting of fluorine-doped tin oxide (FTO), indium-tin-oxide (ITO), TiO2-FTO, ZnO—TiO2-FTO, TiO2-ITO, and ZnO—TiO2-ITO; drop-casting SNPs to form a first AL on the bottom electrode; drop-casting at least one PNP onto the AL; drop-casting SNPs onto the at least one PNP and first AL to form a second AL thereupon; and depositing a top electrode onto the second AL. This method is useful for preparing the photovoltaic of claim 1.

In some of the methods described herein the first AL is twice the thickness of the second AL.

This application also describes a method of generating electricity or converting light into electricity, including illuminating a photovoltaic described herein, with infrared light.

In some embodiments described herein, the electromagnetic near-field associated with the plasmonic nanoparticles overlaps the light absorbing semiconductor. In certain embodiments, the electromagnetic near-field is substantially within 50 nm of the plasmonic nanoparticle. In certain other embodiments, the electromagnetic near-field is substantially within 40 nm of the plasmonic nanoparticle. In certain other embodiments, the electromagnetic near-field is substantially within 45 nm of the plasmonic nanoparticle. In certain other embodiments, the electromagnetic near-field is substantially within 55 nm of the plasmonic nanoparticle. In certain other embodiments, the electromagnetic near-field is substantially within 60 nm of the plasmonic nanoparticle. In certain other embodiments, the electromagnetic near-field is substantially within 65 nm of the plasmonic nanoparticle.

In certain embodiments, the absorption of the plasmonic nanoparticles in the visible wavelengths is minimized. In certain other embodiments, the plasmonic nanoparticle is colloidal and has a core made from an insulator and a shell made out of a metal, and has a scattering-to-absorption ratio greater than 1.

In some embodiments described herein, the plasmonic nanoparticle has a coating including one or more ligands that electrically insulate the nanoparticle.

In certain embodiments, the light-absorbing semiconductor includes colloidal quantum dots.

In certain embodiments, the plasmonic nanoparticles are substantially embedded in the light-absorbing semiconductor.

In yet other embodiments, the photovoltaic device has an illuminated surface closest to incident photons and a back surface furthest from incident photons. In some of these embodiments, the plasmonic nanoparticles are substantially positioned such that they are further from the illuminated surface than the back surface. In one particular embodiment, the plasmonic nanoparticles are approximately two thirds of the distance between the illuminated and back surfaces. In some other embodiments, the nanoparticles are closer to the back surface.

In certain embodiments, the plasmonic nanoparticles have a localized surface plasmon resonance at a wavelength that is optimized for the weakly absorbed portion of the absorption spectrum of the colloidal quantum dots. In certain embodiments, the plasmonic nanoparticles have a localized surface plasmon resonance at wavelengths in the near infrared.

Another embodiment described herein includes a method of making a photovoltaic device. This method includes depositing a first layer of light-absorbing semiconductor nanoparticles, then depositing a layer of plasmonic nanoparticles, then depositing a second layer of light absorbing semiconductor nanoparticles. In one embodiment, the semiconductor nanoparticles are colloidal quantum dots.

In some embodiments described herein, the plasmonic nanoparticles are deposited in a solvent within a ring-like barrier on a substrate. In further embodiments, the solvent is evaporated.

In some embodiments, the present application describes the use of anions as a shell around a nanoparticle or quantum dot. These anions include halogen ions and the thiocyanate ion. Some of these shelled nanoparticles are useful as the light-absorbing nanoparticles of the depleted heterojunctions described above, but are also useful in optoelectronic devices in general, i.e., any devices in which the particles serve to absorb light energy and convert the absorbed energy to an electric current. Examples of anion-containing reagents are quaternary ammonium halides and thiocyanates, and some examples include cetyltrimethylammonium bromide, hexatrimethylammonium chloride, tetrabutylammonium iodide, and tetrbutylammonium thiocyanate.

### EXAMPLES

The following examples are offered to illustrate, but not to limit the claimed invention.

### Example 1

### Photovoltaic Device

This example illustrates the preparation and characterization of a light absorbing semiconductor nanoparticle photovoltaic device that incorporates plasmonic nanoparticles.

In this example, gold plasmonic nanoparticles were incorporated into colloidal quantum dot (CQD) films embedded in photovoltaic devices.

The devices were analyzed with full-wave finite-difference time-domain (FDTD) simulations to evaluate the potential impact of incorporating different types of metal nanoparticles into excitonically-tuned solar cells.

This example is suitable for candidate particles that are (1) compatibility with solution processing; (2) have a size range of less than ˜150 nm for integration in films with thicknesses of less than ˜400 nm; (3) have localized surface plasmon resonances (LSPRs) tunable to the near-IR (NIR) portion of the solar spectrum; or (4) scattering-to-absorption ratios (S) of greater than 1. In some instances, the candidate particles have all of these features. Particles included silver particles and gold particles.

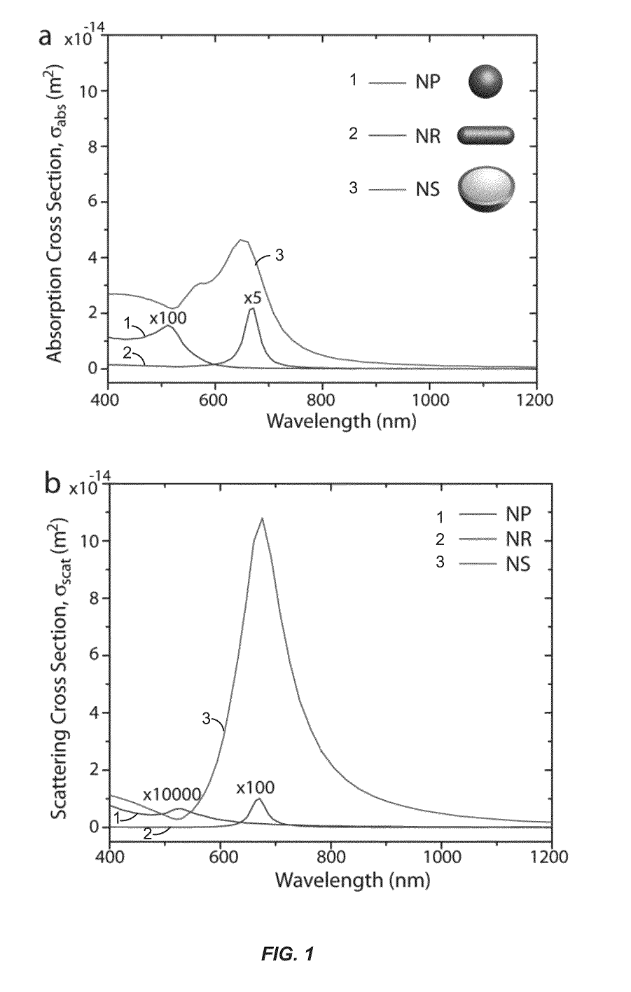

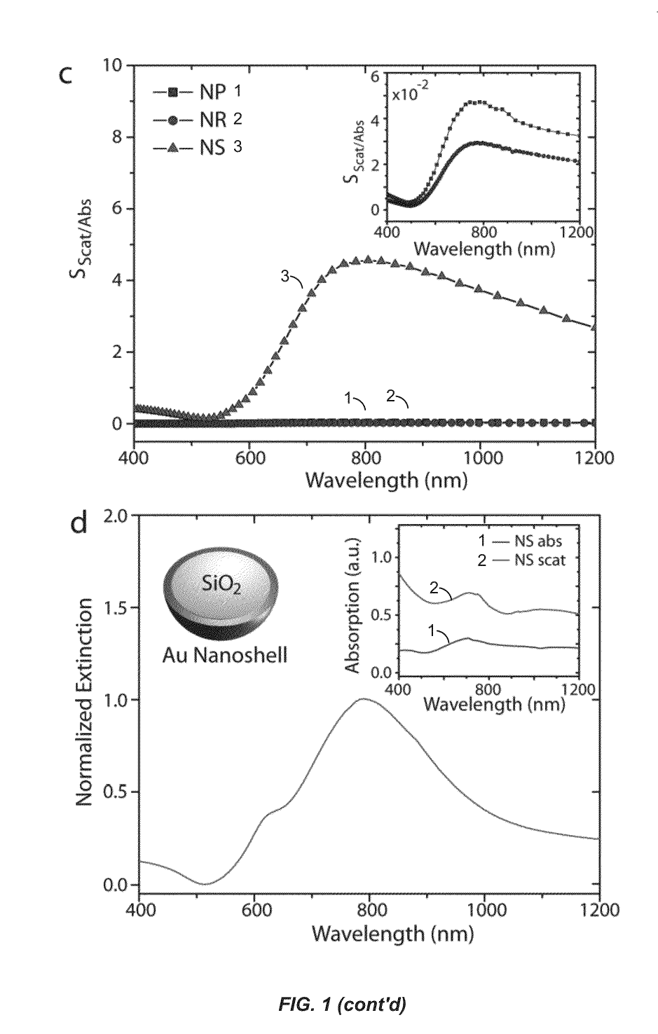

FIG. 1 shows the simulated absorption and scattering cross-sections and the S values for several different types of gold nanoparticles. The dipole resonance of spherical nanoparticles can be tuned in the visible range as a function of the particle radius. At diameters greater than 150 nm, broadband multipole modes arise in the near infrared (NIR) spectral range. In general, these nanoparticles generally exhibit lower LSPR amplitudes.

A second candidate for infrared-tunable plasmonic particles was gold nanorods. These exhibit two spectrally separated LSPRs due to the coherent oscillation of the conduction band electrons along each of the particle axes (transverse and longitudinal), and the longitudinal plasmon can be spectrally tuned through the NIR by varying the aspect ratio. For some nanorods, a strong electric field exists within the metal and results in a S of much less than 1 over all wavelengths of interest. For example, see this phenomenon for spherical nanoparticles in FIG. 1c.

FIG. 1a shows the absorption as a function of particle size and shape. FIG. 1b shows the scattering cross-section spectra as a function of particle size and shape. The scattering cross-sections take into account both near- and far-field effects. Spherical nanoparticles (NP, diameter=20 nm) have a limited response beyond λ=600 nm, while nanorods (NR, diameter=10 nm, length=40 nm) and nanoshells (NS, core diameter=120 nm, shell thickness=15 nm) have tunable localized surface plasmon resonances (LSPRs) in the infrared wavelength region. A medium of index 1 was used. The nanoparticle and nanorod spectra are scaled as noted next to the curves for visual clarity. FIG. 1c shows the calculated scattering-to-absorption ratios (S) showing that nanorods and nanoparticles (having physical dimensions in the range 10 nm to 400 nm) are absorptive while nanoshells have broadband external field enhancement which exceeds parasitic absorption. The inset shows the same data for nanorods and nanoparticles on a smaller scale.

FIG. 1d shows the experimental extinction spectrum of nanoshells in a methanol solution. Insets show a schematic of a gold nanoshell cross-section (left) and measured scattering and absorption of nanoshell films (right).

### Example 2

### Nanoshells

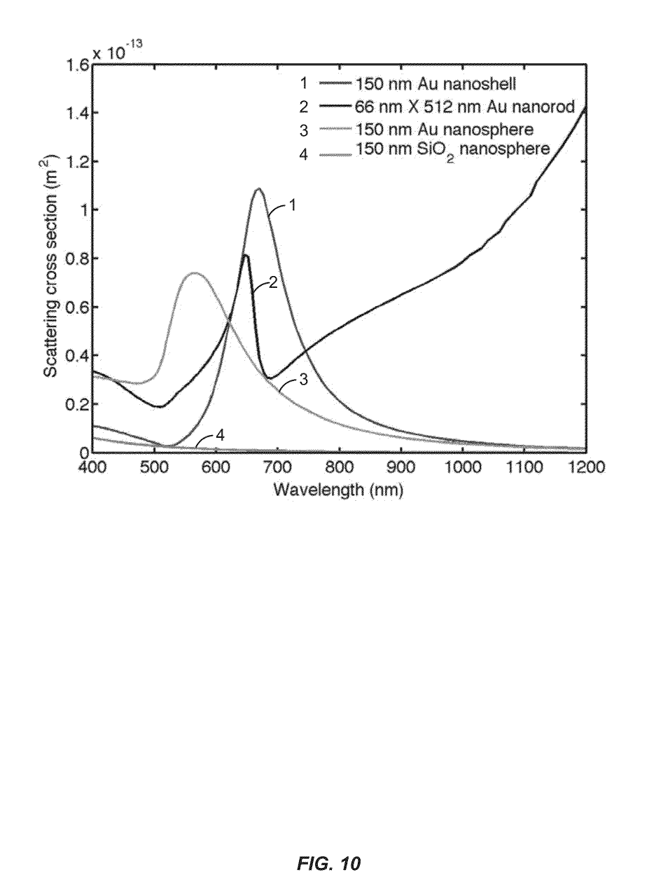

This example analyzes spherical dielectric-metal core-shell nanoparticles, a.k.a. nanoshells. FIG. 1d shows the measured extinction spectrum of nanoshells in methanol solution with a LSPR centered at 800 nm with a full-width at half-maximum of 280 nm. The extinction (absorption+near- and far-field scattering) cross-section is 3-5 orders of magnitude larger than that of either spherical nanoparticles or nanorods (FIG. 1a,b). Due to the presence of a thin metallic shell (˜15 nm), the optical interaction volume of these particles is therefore much larger. This in turn reduces the areal density required to scatter incident light completely while minimizing absorption. The theoretical S factor reaches its maximum at 4.5, and is larger than 3 over a wide spectral range in the near-infrared region (FIG. 1c). Additional calculations for large nanorods (66 nm in diameter and 512 nm in length), spherical nanoparticles (150 nm in diameter), and spherical dielectric particles (150 nm in diameter) (FIG. 10) show that gold nanorods and nanospheres require sizes greater than 150 nm in at least one dimension to achieve S values comparable to the nanoshells at the wavelengths of interest.

This makes the rods and spheres difficult to incorporate into thin film CQD devices. The nanoshells offer superior scattering cross-sections at the near infrared wavelengths of interest compared to other structures with comparable volumes.

FIG. 10 shows 3D FDTD simulated scattering cross sections for three different types of spherical nanoparticles with diameter=150 nm: gold nanoshells (1), gold nanospheres (3), and silica nanospheres (4), and gold nanorods with a comparable volume and resonance wavelength (2). For the same size particles, gold nanoshells have a higher scattering cross section than gold spheres and nanorods, and their peak resonance wavelength is slightly redder (more red-shifted) than that of the spheres. The large nanorod dimensions required to achieve comparable scattering cross sections and resonance wavelengths as the optimal gold nanoshells are not compatible with CQD thin film integration. Silica spheres show low scattering efficiency at infrared wavelengths due to the limited dielectric constant contrast between silica and the background medium.

### Example 3

### Nanoshell Scattering Factor

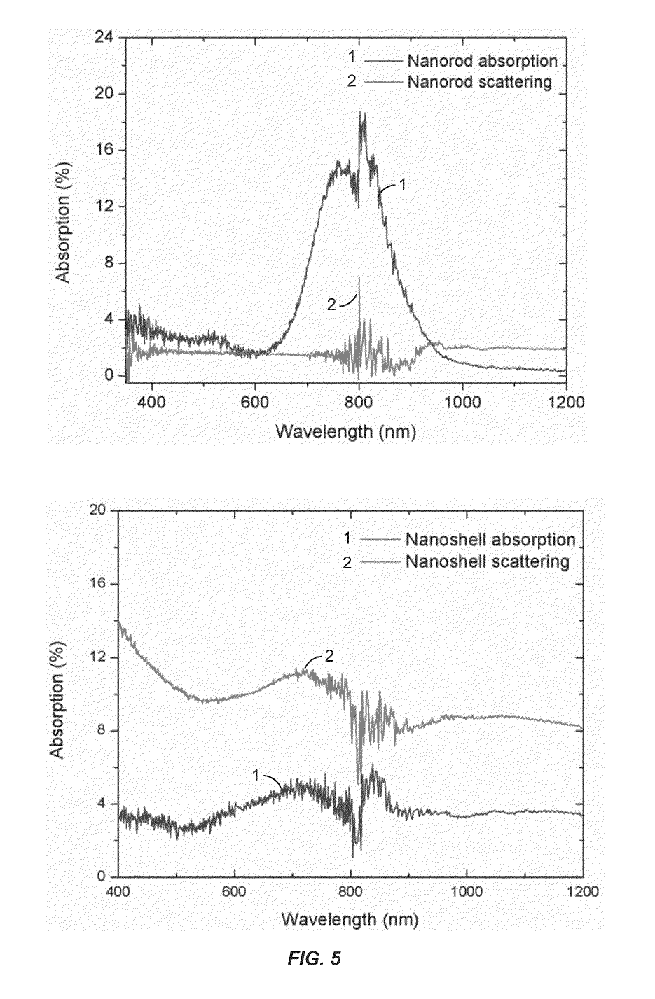

This Example verifies S>1 for nanoshells by experimentally measuring the relative scattering and absorption contributions. A thin layer of nanoshells was deposited by drop-casting from the solution-phase onto a glass slide and separated the absorption and scattering components using integrating sphere spectrophotometry (see Methods below). FIG. 1d inset shows that, in the solid state, S is at least 2 over all wavelengths of interest (e.g., 400-1200 nm). In contrast, the S of nanorods deposited by a similar method was measured to be much less than 1 over the same wavelength range (FIG. 5).

FIG. 5 shows the UV-Vis-NIR absorption and scattering spectra taken in an integrating sphere for a drop-cast ensemble of (a) nanorods and (b) nanoshells on an ITO-coated glass substrate.

In FIG. 5, absorption (1) was measured by tilting the sample at a slight angle relative to the illumination beam with all other ports closed so that all directly transmitted, reflected, and off-angle-scattered light was collected by the detector. Scattering (2) was measured by orienting the sample normal to the incident beam with a port opposite the input port open so that only the off-angle-scattered light was detected. The 100% transmission baseline for both curves was measured with a bare ITO-coated glass substrate oriented at a slight angle relative to the illumination beam. The nanorods ensemble had a large absorption peak around 800 nm, while the scattering intensity was flat, to within the measurement sensitivity, across the entire spectrum, indicating that the bare nanorods have a disadvantageous scattering-to-absorption ratio in the spectral range of interest for integration with CQD photovoltaics. The scattering intensity was larger than the absorption signal across the entire spectrum for the nanoshell case, indicating that the bare nanoshells have an advantageous scattering-to-absorption ratio for integration with CQD photovoltaics.

The Examples herein show that the scattering component is the major contribution from the measured extinction of nanoshells, as shown in FIG. 1d. This means that they are less absorptive and thus meet the criteria for incorporation into excitonic solar cells, including (1) compatibility with solution processing; (2) have a size range of less than ˜150 nm for integration in films with thicknesses of less than ˜400 nm; (3) have localized surface plasmon resonances (LSPRs) tunable to the near-IR (NIR) portion of the solar spectrum; or (4) scattering-to-absorption ratios (S) of greater than 1.

### Example 4

### Thin-Film Photovoltaic Device with Nanoshells

This Example analyzes the effects of incorporating gold nanoshells into thin-film photovoltaic devices. Colloidal quantum dots offer wide-ranging bandgap tunability through the quantum size effect, and have shown increasing photovoltaic performance. The absorption spectrum of this material exhibits a peak at the excitonic transition: however, light in the NIR spectral region (700-1000 nm) is not fully absorbed in films of thickness ˜400 nm, the transport length (sum of the minority carrier diffusion length and the width of the depletion region at the maximum power) of today's best photovoltaic CQD films. Past strategies for overcoming this absorption-extraction compromise include interpenetrating the acceptor material and the CQD film to increase the width of the depletion region using TiO₂ nanostructures, a concept analogous to bulk heterojunction cells in organic photovoltaics. Nevertheless, planar cells having an area-minimizing charge-separating electrode have to date offered the best performance. Plasmonic enhancements would address the present-day absorption-extraction trade-off problem by increasing light absorption for a given quantum dot film volume, and for a given planar charge-separating interfacial area.

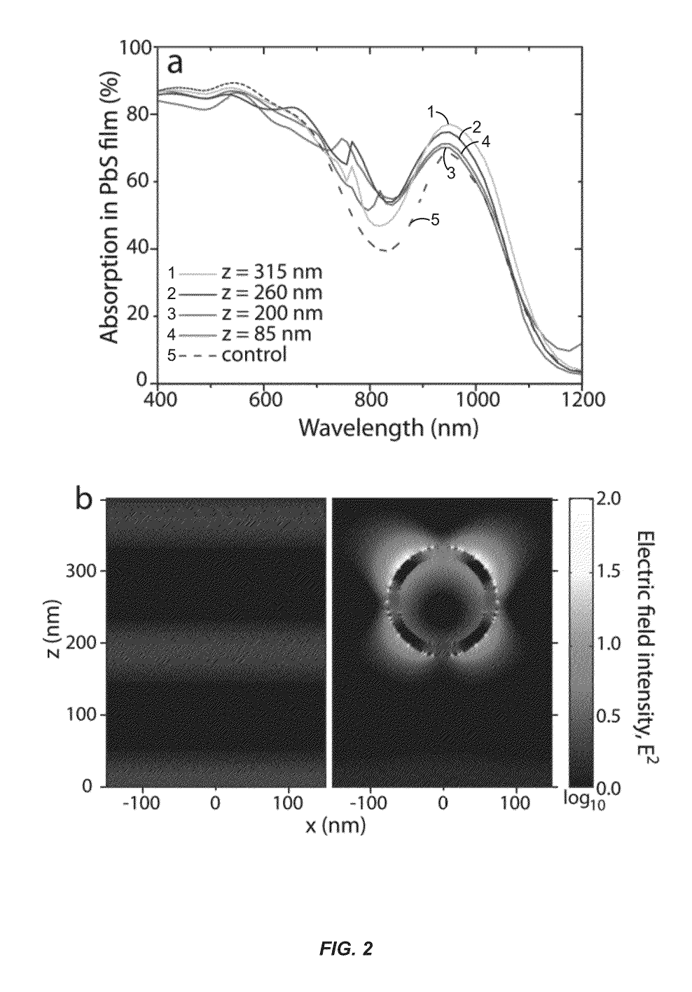

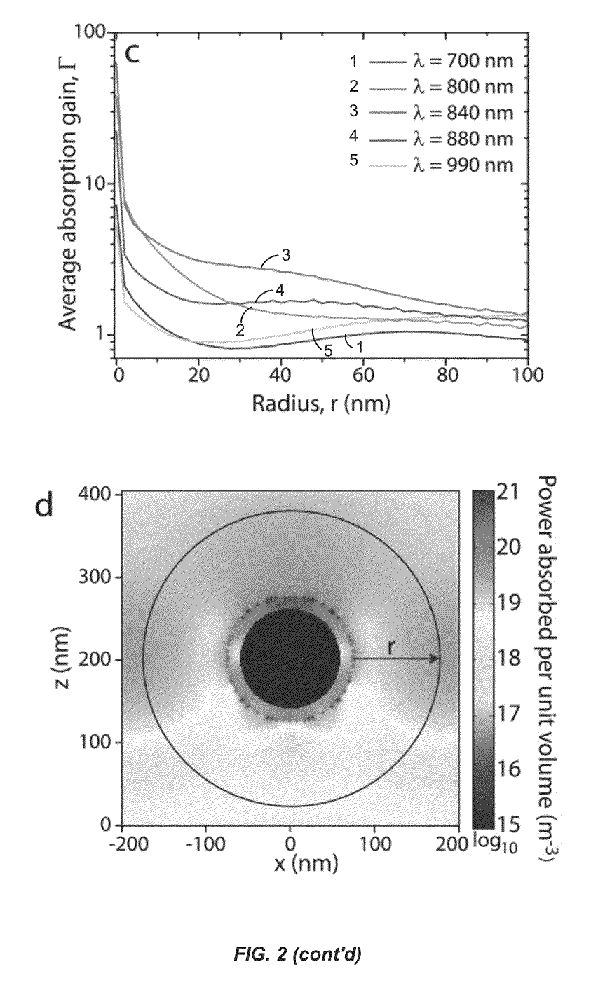

In FIG. 2, FDTD simulations show the optical properties of gold nanoshells embedded within PbS CQD films. FIG. 2a-b shows the relative enhancements expected from an array of nanoshells at various vertical locations, z, within the CQD film. If the nanoshells were located too close to the illuminated side of the film, this led to significant parasitic absorption in the visible spectral range (400-600 nm) which limited the optical enhancement.

Instead, if the nanoshells were located toward the rear gold reflector, then this location allowed for more effective scattering of weakly-absorbed infrared radiation while minimizing the impact on short-wavelength light. Placing the nanoshell too close to the back of the device, near the reflector, reduced the volume of CQD material which interacted with the enhanced near-field.

Specifically, FIG. 2a shows absorption spectra (including back-reflector) in a 400 nm thick PbS quantum dot film with nanoshells embedded at different values of z, the distance from the PbS bottom-illuminated interface to the center of the nanoshells. The nanoshells are periodically spaced by an average of 300 nm.

### Example 5

### Comparison of Enhanced and Unenhanced Films

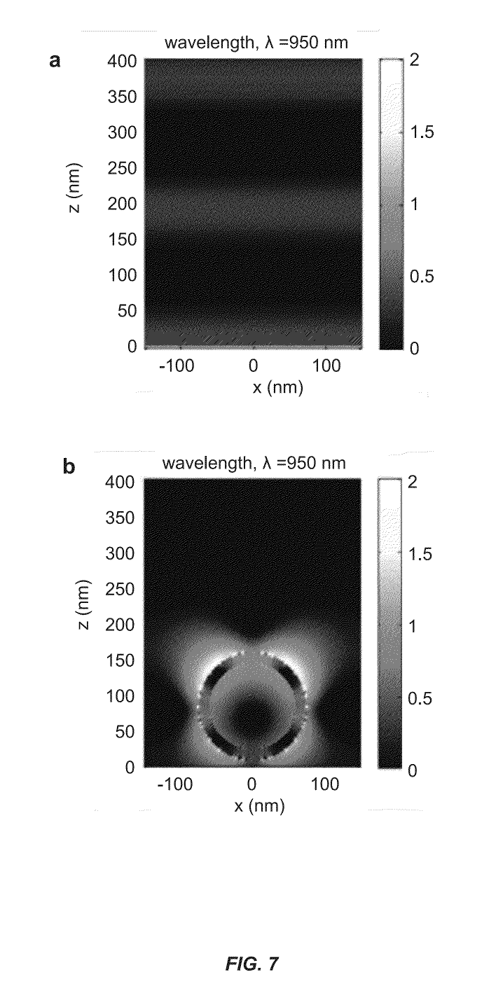

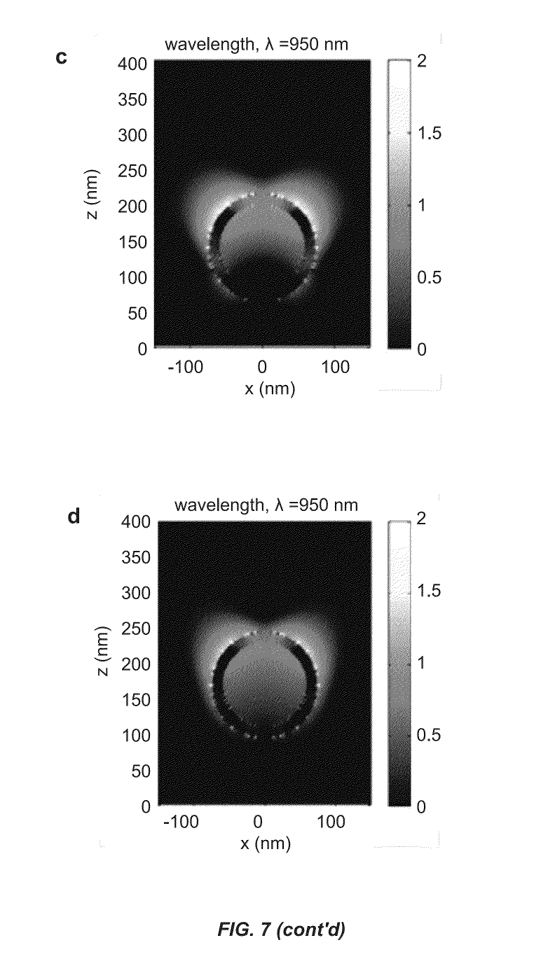

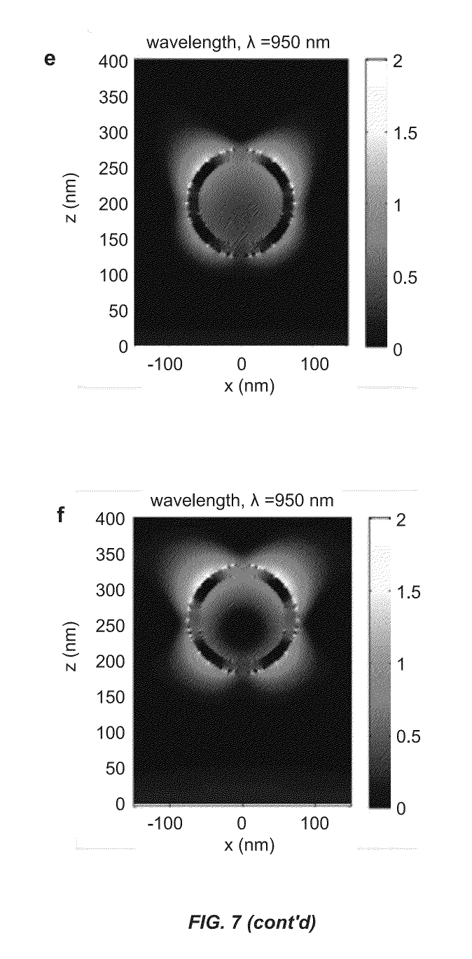

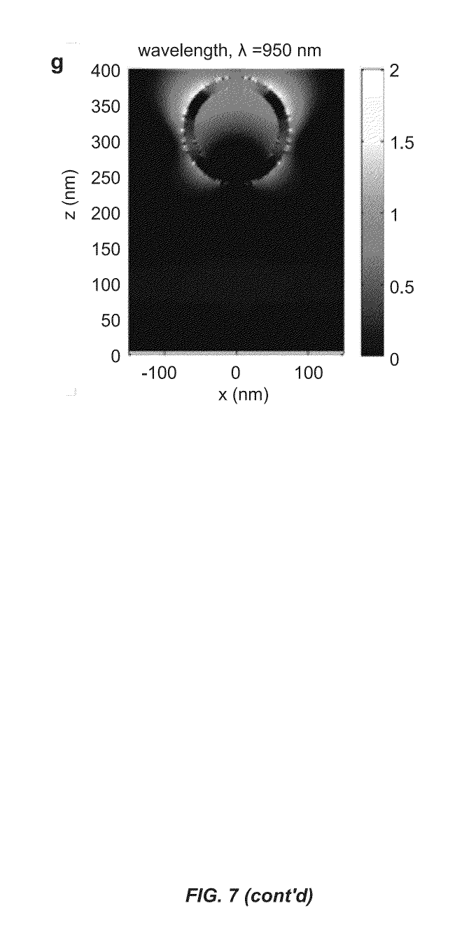

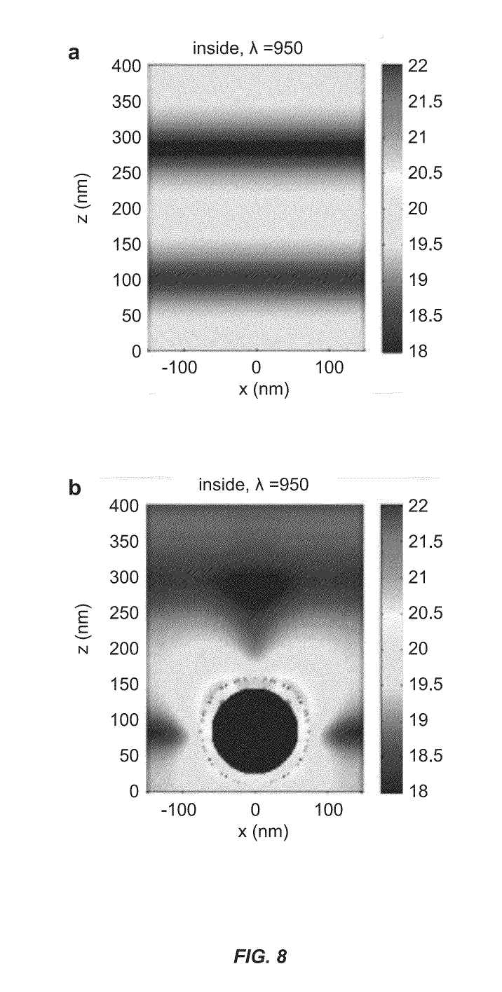

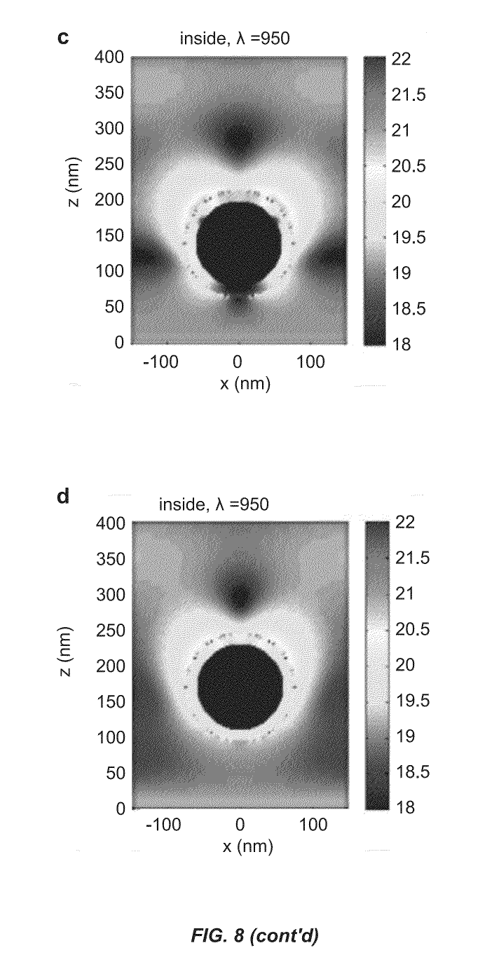

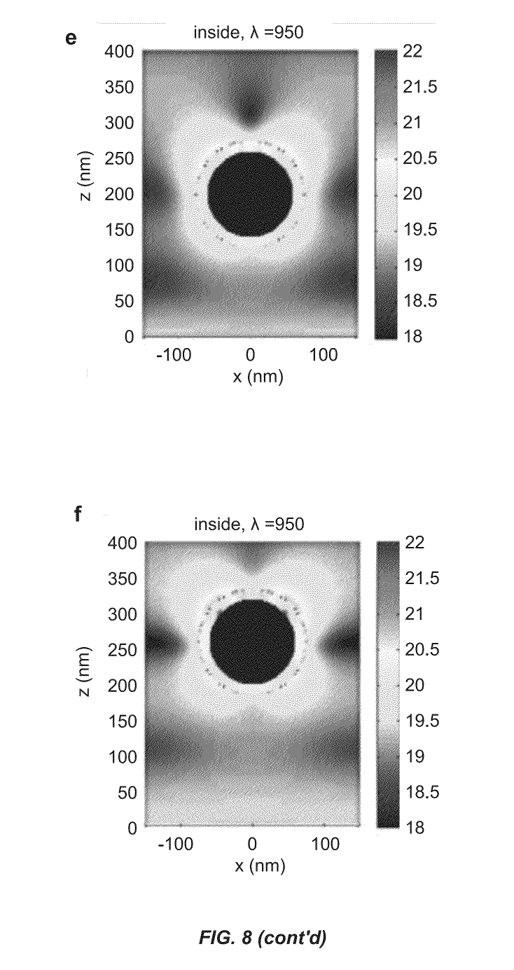

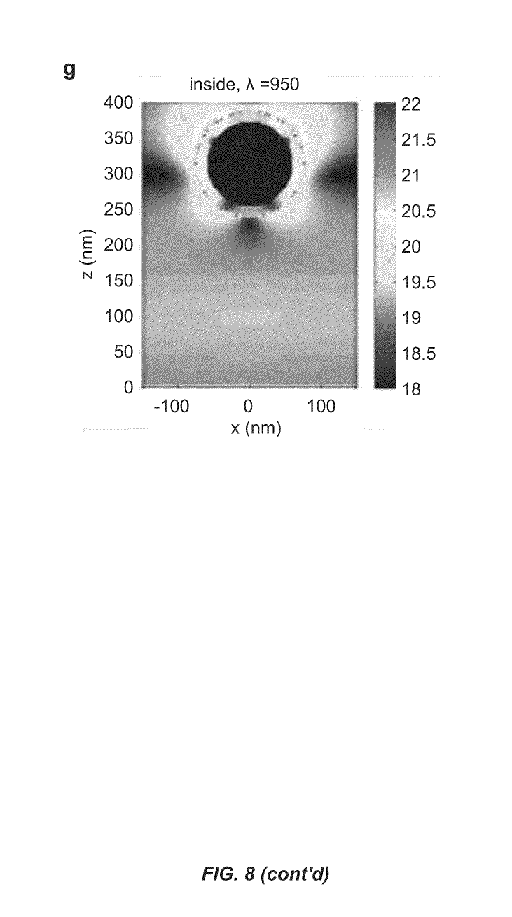

FIG. 7 shows the electric field intensity profiles at the quantum dot exciton wavelength (950 nm) for (a) an unenhanced (no nanoshells) PbS CQD film and (b-g), PbS CQD films with a nanoshell embedded at different z-locations, showing the variation of the field profile with nanoshell placement. FIG. 8 shows the absorption profiles at the quantum dot exciton wavelength (950 nm) for (a) an unenhanced (no nanoshells) PbS CQD film and (b-g), PbS CQD films with a nanoshell embedded at different z-locations, showing the variation of the absorption profile with nanoshell placement.

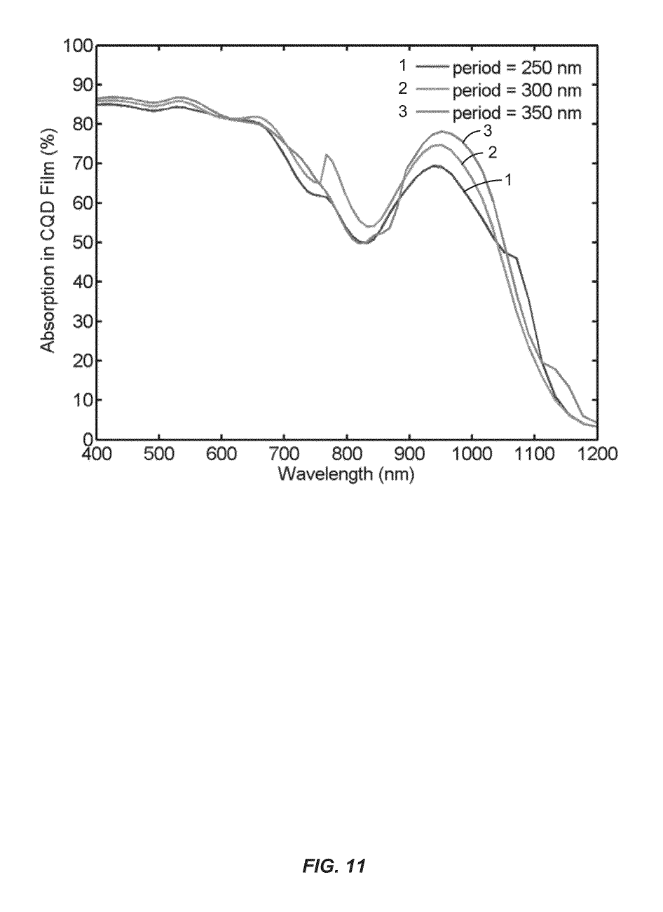

FIG. 11 shows the results for several different periodic spacings which indicate that the qualitative spectral shapes and intensities are independent of simulated period. The maximum integrated current is found to occur when the nanoshell is at a z position of 260 nm. FIG. 2b shows the electric field intensity (E₂) profiles in the control film (left) and plasmonic film (right) on a log scale at the CQD exciton wavelength, λ=950 nm.

FIG. 11 shows 3D FDTD simulations of absorption spectra (including back-reflector) in a 400 nm thick PbS quantum dot film with nanoshells embedded and periodically spaced by different distances. The fine details of the spectra are influenced by the spacing, but the qualitative spectral shapes and intensities are independent of simulated period.

### Example 6

### Enhancement with Nanoshells in Colloidal Quantum Dot Films

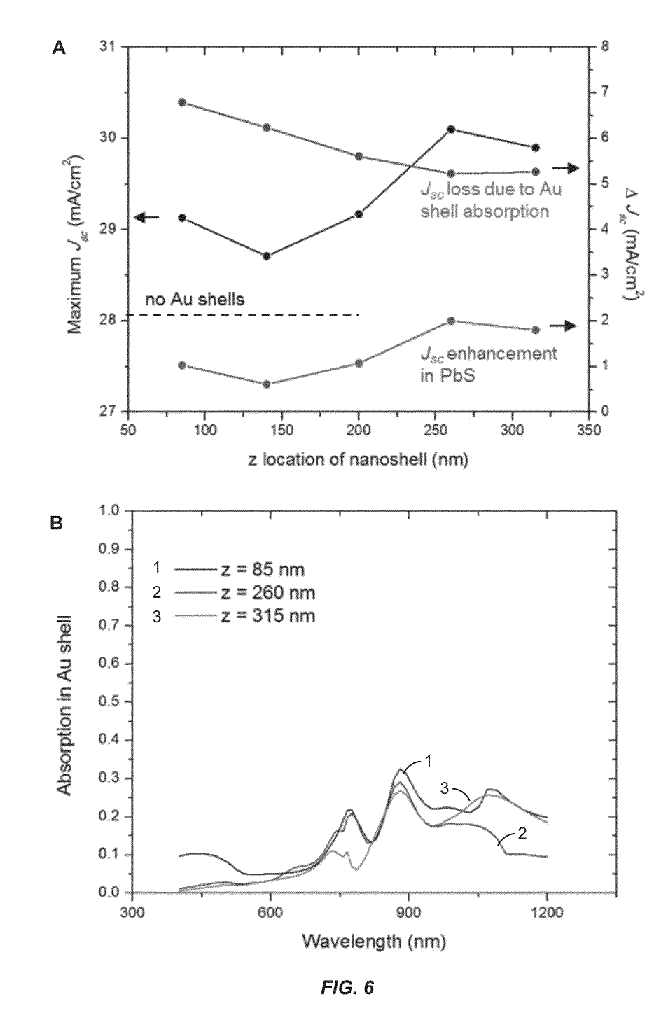

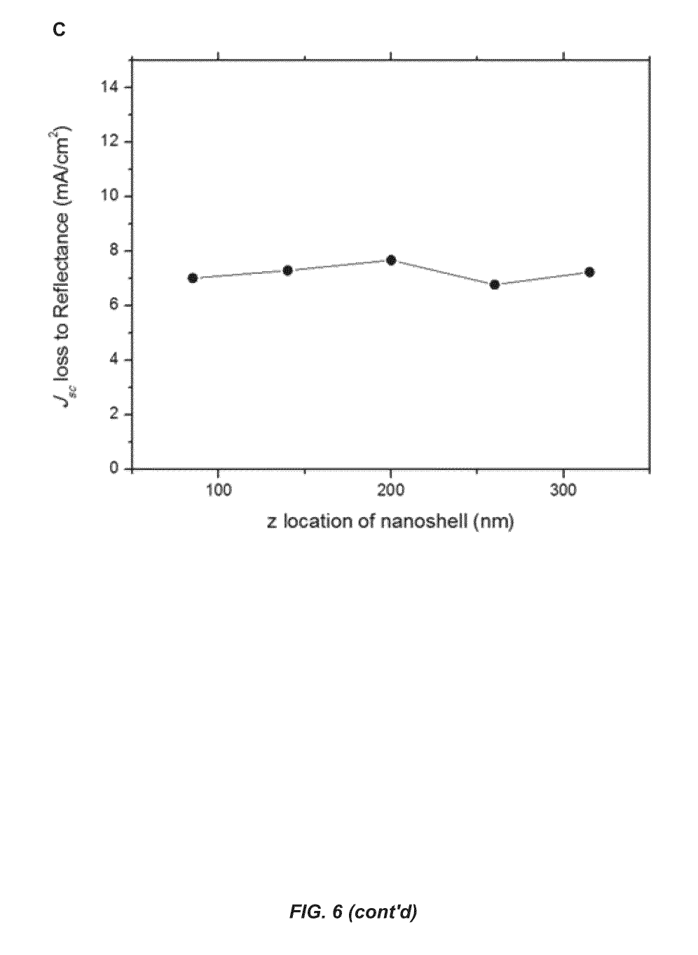

FIG. 6 shows the optimal enhancement that would occur when nanoshells were placed approximately two-thirds of the way into the CQD film as measured from the illuminated interface. In this Example, relatively large-diameter nanoshells displaced the equivalent volume of CQDs, indicating that the plasmonic effect more than overcame the loss of absorbing PbS volume.

FIG. 6a shows FDTD simulation results showing the maximum expected J_{SC} (black curve) calculated by integrating the PbS absorption curves in FIG. 2a over the AM 1.5 solar spectrum and assuming perfect charge collection. Also shown is the J_{SC} loss due to absorption in the gold shell, and the J_{SC} enhancement in the PbS film over the planar control. FIG. 6b shows the simulated absorption in the gold nanoshell for different z-locations in the CQD film. The shell absorption loss decreases as it moves toward the back reflector, with an optimal J_{SC} at approximate location z=260 nm. FIG. 6c shows the simulated J_{SC} loss due to reflection off the front surface of the device as a function of the z-location of the nanoshell. The nanoshell placement in this Example has a minimal effect on reflection, as shown by the flat response.

### Example 7

### Field Enhancement

This Example shows the relative contribution of the observed absorption enhancement attributable to the field enhancement. In FIG. 2c-d nanoshells were embedded in a film of CQD absorber material and the average absorption gain, Γ, was calculated. In this Example, the average absorption gain is defined as the power absorbed in the nanoshell case normalized by the absorption in the film without nanoshells. FIG. 2b shows a plot of Γ as a function of radial distance, r, from the center of the nanoshell for different wavelengths. FIG. 2b shows a significant absorption enhancement in the surrounding PbS film. The absorption gain is largest for wavelengths near λ=840 nm and decays quickly from the nanoshell surface, remaining greater than one for a range of wavelengths near the plasmonic resonance out to 100 nm from the nanoparticle. This indicates that resonant near-field enhancement is the primary mechanism contributing to enhanced absorption with a small additional contribution from enhanced far-field scattering into the optical modes of the device.

FIG. 2c depicts the average absorption gain, Γ, the ratio of absorption in the nanoshell-embedded PbS film to the unenhanced PbS film, as a function of radial distance, r, from the edge of the nanoshell plotted for a range of wavelengths around the LSPR. FIG. 2d shows the absorption profile (log scale) at λ=840 nm of a nanoshell embedded in a PbS CQD film demonstrating the strong electromagnetic near-field in the vicinity of the nanoshell. The power absorbed per unit volume is in units of m⁻³ (absorbed power per unit volume is normalized to the source power).

### Example 8

### Solar Cell

This Example shows the design of a solution-processed plasmonic CQD solar cell employing gold nanoshells. Nanoshells consisting of an inner core radius of 60 nm (SiO₂) and outer radius of 75 nm (Au) are capped with polyvinylpyrrolidone (PVP). These nanoshells show a broad LSPR at 800 nm in methanol solution (FIG. 1d), a solvent chemically compatible with our CQD films. These solar cells included a depleted heterojunction architecture, and the quantum dot film was formed on top of a TiO₂ electrode using a layer-by-layer process (see Methods). The nanoshell solution was deposited by drop-casting and drying under low vacuum after two-thirds of the total CQD material had been deposited. The finished device consisted of the remaining third of the CQD layers and an evaporated ohmic contact consisting of MoO₃/Au/Ag.

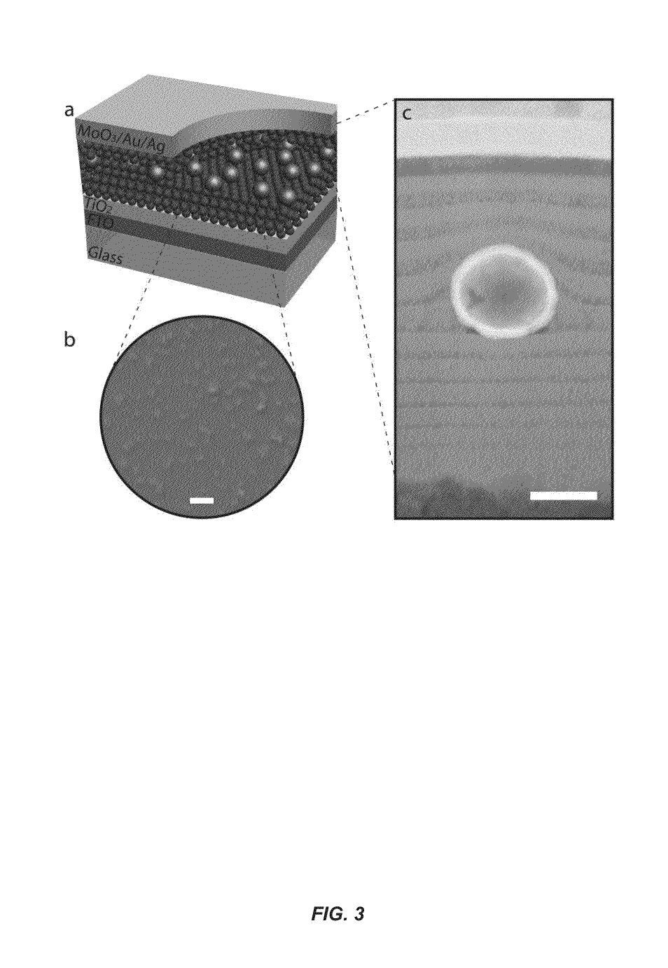

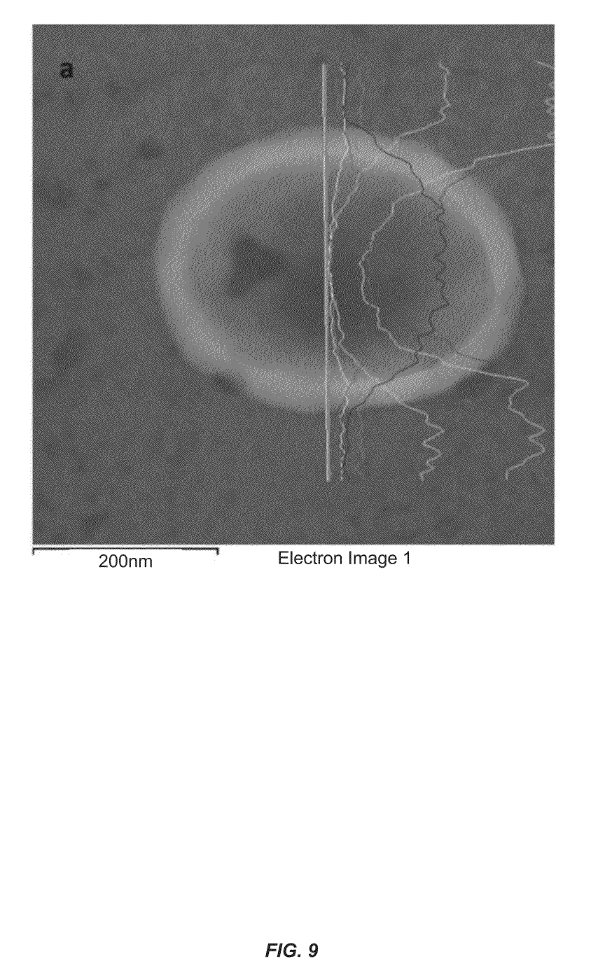

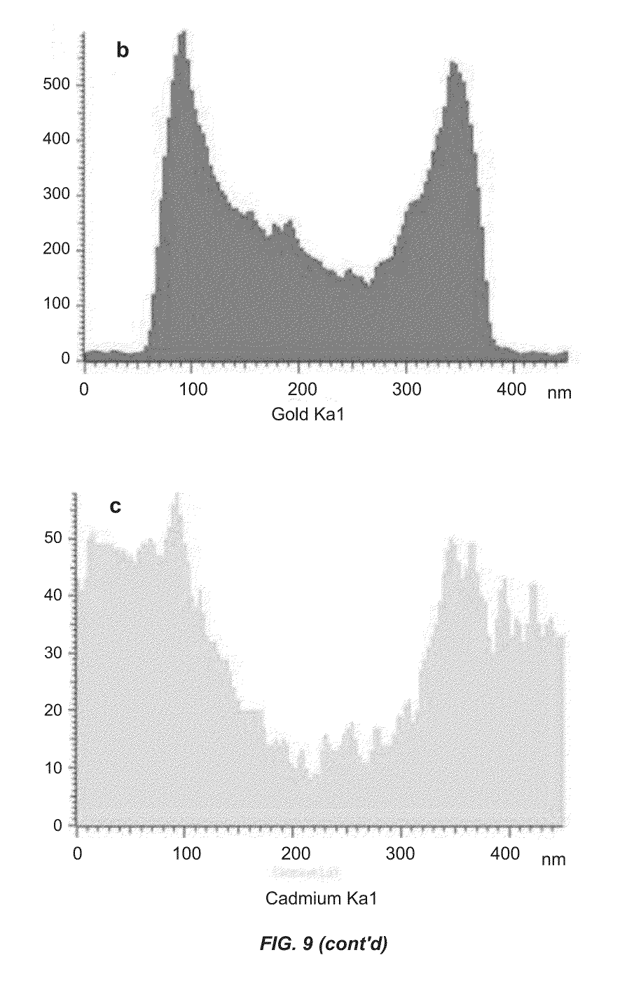

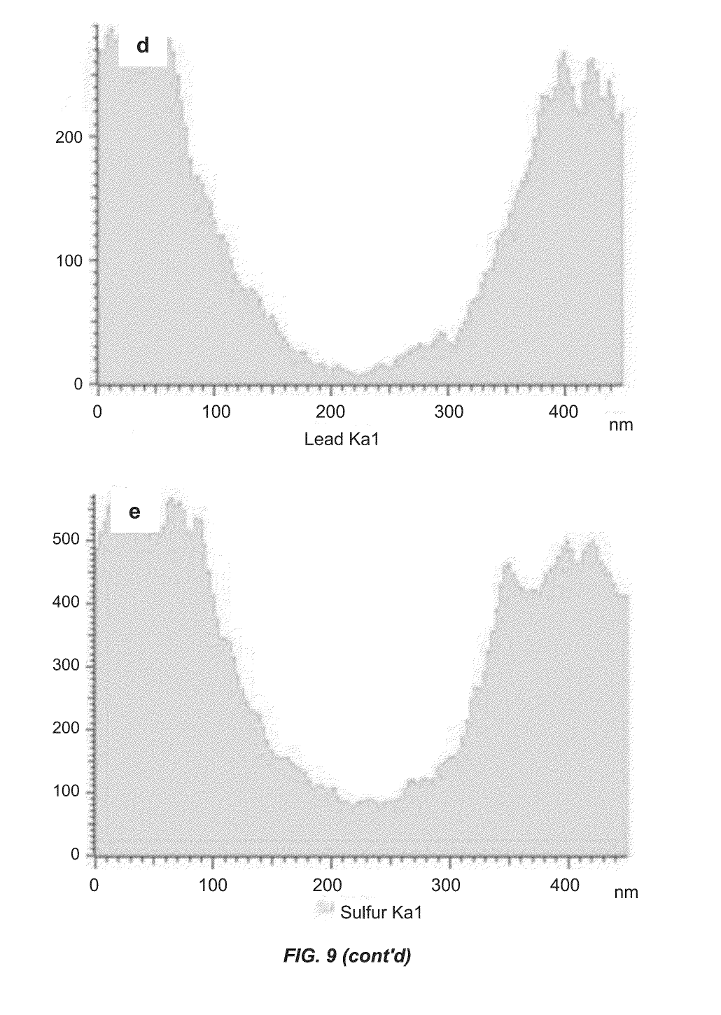

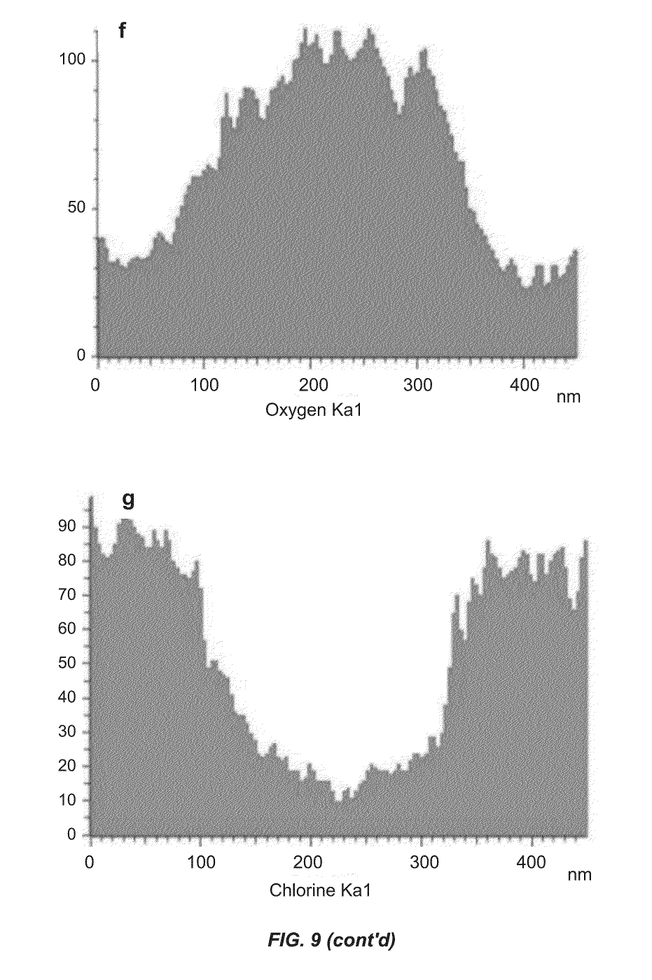

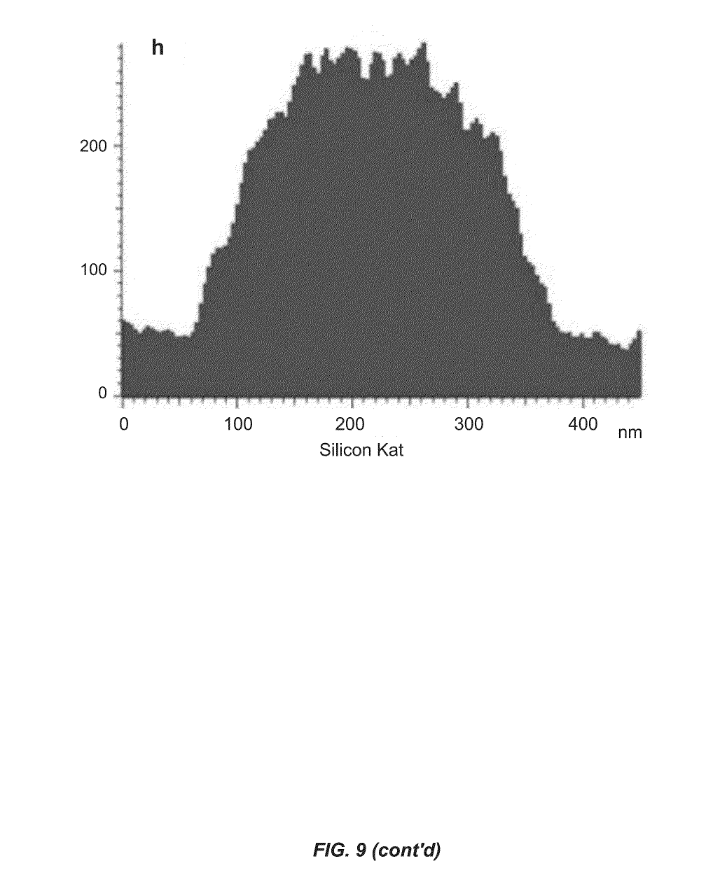

FIG. 3a shows a schematic representation of a plasmonic CQD solar cell design. Included is a 980 nm bandgap PbS CQD and a TiO₂ electron acceptor. FIG. 3b shows a top-view low-magnification SEM image, showing an estimated average surface coverage of approximately 10 nanoshells per square micrometer. The average nanoshell areal density was selected in this Example to provide full optical coverage based on the peak scattering cross-section of approximately 10⁻¹³ m² while minimizing inter-particle coupling effects due to undesired aggregation. FIG. 3c shows a cross-sectional TEM image of a sample prepared via focused ion beam milling of the constituent layers and shows a single gold nanoshell embedded in a PbS CQD film (scale bar=100 nm). Energy dispersive X-ray analysis confirms the atomic composition of nanoshells embedded in CQD layers (FIG. 9). Also visible are the individual spin-cast CQD layers which surround and embed the gold nanoparticle. FIG. 9 shows the (a) cross-sectional TEM image of a gold nanoshell embedded in a PbS CQD film with a line plot showing elemental distribution as measured by energy-dispersive X-ray analysis, where count histograms for each element along the line scan are shown for (b) gold, (c) cadmium, (d) lead, (e) sulfur, (f) oxygen, (g) chlorine, and (h) silicon.

### Example 9

### Absorption Enhancement in a Photovoltaic Device

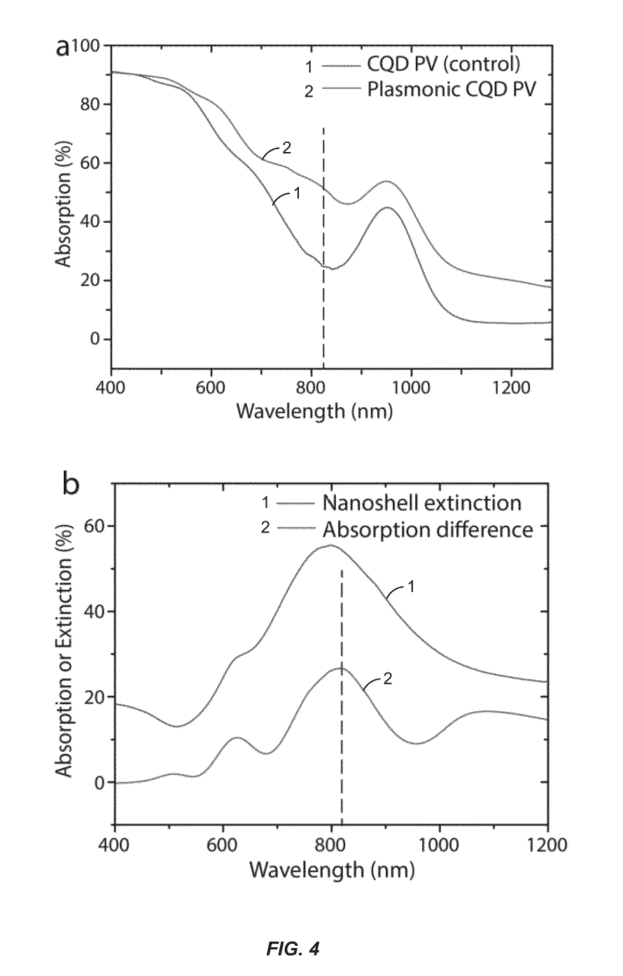

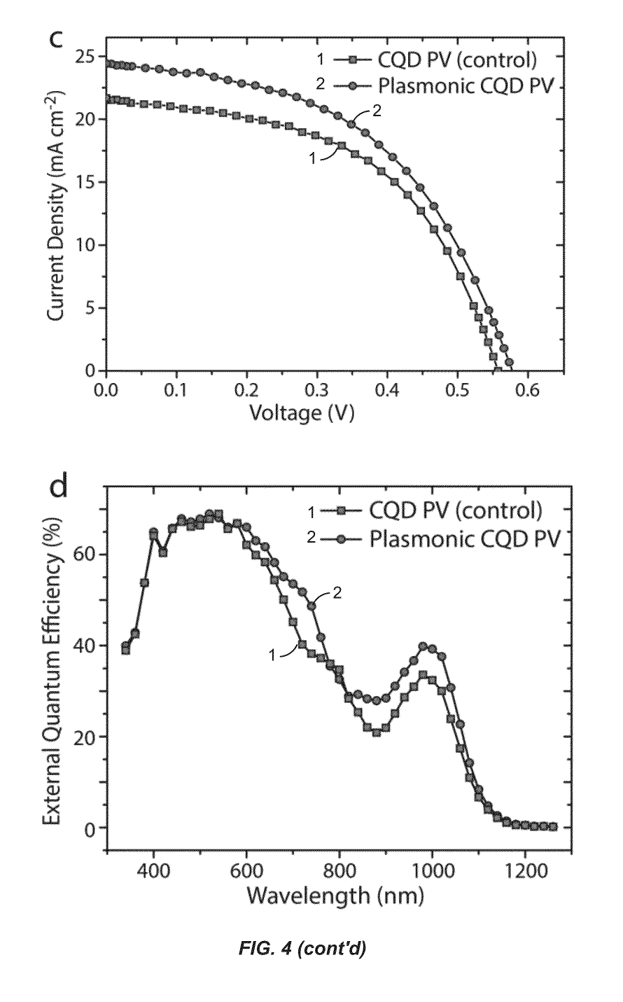

The absorption spectra in a single pass through the CQD films were measured using integrating sphere spectrophotometry. FIG. 4 shows the performance of a photovoltaic device incorporating plasmonic and CQD nanoparticles. Single-pass absorption spectra of representative CQD films with and without embedded nanoshells are shown in FIG. 4a. FIG. 4b depicts the absorption enhancement which exhibits a peak near 820 nm and closely matches the nanoshell extinction spectrum, suggesting that a resonant effect accounts for the observed enhancement. FIG. 4c shows the measured current-voltage characteristics under AM 1.5 simulated solar illumination for representative control and plasmonic devices. J_{sc} enhancement of 13% and PCE enhancement of 11% were observed in the plasmonic device. FIG. 4d represents the external quantum efficiency spectra of control and plasmonic CQD solar cells. A peak 35% enhancement centered at a wavelength of 880 nm was observed in the plasmonic device.

The spectra of two representative samples with and without nanoshells are shown in FIG. 4a. By subtracting the absorption curves ofa nanoshell-embedded CQD film and a bare CQD film as a control, a broadband absorption enhancement was observed as high as 100%, centered near the plasmonic LSPR at 820 nm (FIG. 4b). This absorption enhancement is primarily attributed to the near-field scattering from nanoshells and also includes contributions from absorption in the nanoshells themselves and far-field scattering. The resonance is red-shifted by approximately 20 nm relative to that measured in solution due to the higher index of the surrounding medium (n_{CQD}˜2.6). Enhancements at wavelengths above 1,000 nm are expected to originate from enhanced absorption in the substrate and gold top contact due to multiple scattering. If we consider the high scattering-to-absorption ratio of nanoshells, we expect most of the measured absorption enhancement at wavelengths shorter than the CQD film bandgap to originate from absorption in the quantum dot film and not from parasitic absorption in the nanoshells, as supported by simulations (FIG. 2).

### Example 10

### Performance of a Photovoltaic Device

The performance of plasmonic CQD devices with nanoshells incorporated was evaluated in solar cell devices measured under simulated AM 1.5 solar illumination (see Methods). FIG. 4b shows current-voltage curves of the higher-performing devices. Overall power conversion efficiency (PCE) enhancement of 11% were observed over a non-plasmonic device (PCE=6.9% vs. 6.2% for the control). The enhancement in performance is primarily due to the 13% enhancement in short circuit current density, J_{SC} (24.5 mA cm₋₂ vs. 21.6 mA cm₋₂ for the control), while there is no statistically significant enhancement or degradation of the open circuit voltage, V_{OC}, or fill factor, FF (Table 1). This trend indicates that fidelity was maintained in the thin films, added recombination effects resulting from nanoshell integration were overcome, and simultaneously the density of photogenerated carriers was increased by enhancing the CQD film absorption.

In order to test the hypothesis that the performance enhancement was due to rational control of the properties of the plasmonic-excitonic solar cell, a series of negative control devices using highly absorptive nanorods were prepared. The concentration of the deposited nanorod solution was controlled to match the measured peak extinction of the optimized nanoshell solution to within 20% in order to operate in a comparable optical coverage regime. The results are summarized in Table 2, and show no significant change in device current for the nanorod devices compared to the controls. These results indicate that plasmonic-excitonic solar cells must follow strict design criteria such as those outlined previously in order to benefit from plasmonic enhancements.

External quantum efficiency (EQE) measurements were used to analyze in greater detail the origins of enhanced photocurrent in plasmonic CQD solar cells. The results of EQE measurements of two representative samples are shown in FIG. 4c. A strong spectral correlation was observed between the enhanced absorption shown in FIG. 4a and the enhanced quantum efficiency. The peak EQE enhancement of approximately 35% occurs at a wavelength near 880 nm, which falls within the full-width at half-maximum of the nanoshell LSPR and is very close to the wavelength of peak absorption enhancement suggesting a resonant near-field effect due to the plasmonic nanoshells. It is thought that the peak wavelength for near-field measures of gold plasmonic particle resonances should be red-shifted compared to the far-field and absorption peak wavelengths, which is consistent with the possibility that most of the device EQE enhancement is attributable to plasmonic near-field effects.

Plasmonic and control EQE spectra and the internal quantum efficiency (IQE) spectrum were used for the control device (calculated by dividing the EQE spectrum by the double-pass absorption spectrum) to quantify the relative contributions of enhanced absorption in the CQD film and absorption in the nanoshells to the absorption difference spectrum shown in FIG. 4b.

The enhanced absorption in the CQD film due to the presence of the nanoshells is given by the EQE difference spectrum divided by the IQE spectrum, and the parasitic absorption in the nanoshells is given by the difference between this value and the difference in the absorption spectra. Integrating over all wavelengths, it was determined that 54% of the enhanced absorption occurred in the CQD film and 46% of the enhanced absorption occurred in the nanoshells. This verifies that S for the nanoshells is slightly greater than one. The EQE difference spectrum is zero or positive across all wavelengths. This indicates that the presence of parasitic absorption in the nanoshells did not detract from device performance at any photon energy.

Plasmonic control of light on the nanoscale has shown wide applicability to sub-wavelength-scale sensing and imaging enhancements. The embodiments described here demonstrated spectrally-matched infrared enhancement in all-solution-processed thin film plasmonic-excitonic solar cells. Some of these embodiments used the sub-wavelength near-field scattering effects of colloidal plasmonic nanoparticles to increase effective absorption lengths for NIR photons to length scales much larger than the absorbing film thickness.

### Example 11

### Colloidal Quantum Dot Synthesis

PbS quantum dots were synthesized according to a previously published method by Hines, M et al. in “Colloidal PbS nanocrystals with size-tunable near-infrared emission: observation of post-synthesis self-narrowing of the particle size distribution.” Adv. Mater. 15, 1844-1849 (2003). Then, a solution-phase metal halide (CdCl₂) treatment was used as similarly set forth in by Ip, A H et al. in Nat. Nanotech. 7, 577-82 (2012). 1.0 ml metal halide precursor (CdCl₂ and tetradecylphosphonic acid (TDPA) dissolved in oleylamine with 13.6:1 Cd:TDPA molar ratio) was introduced into the reaction flask after sulfur source injection during the slow cooling process. The PbS CQDs were isolated by the addition of 60 ml of acetone followed by centrifugation after the reaction temperature reached 30-35 OC. The nanocrystals were then purified by dispersion in toluene and reprecipitation with acetone/methanol (1:1 volume ratio) and re-dissolved in anhydrous toluene. The solution was washed with methanol three times with the final redispersion in octane at 50 mg ml₋₁.

### Example 12

### Finite-Difference Time-Domain Simulations

Finite-difference time-domain (FDTD) simulations were carried out using software package Lumerical FDTD solutions version 8 (http://www.lumerical.com). Scattering and absorption cross-sections were determined following the Mie scattering method. A total-field scattered-field (TFSF) source surrounds the particle of interest. A broadband (λ=400-1200 nm) source, polarized along the cylinder axis, was injected. The region is surrounded by Perfectly Matched Layers (PMLs) which absorb most incident radiation over a wide range of angles. Two analysis groups, one inside the source boundary (measuring total field) and one outside the source boundary (measuring scattered field) calculate the optical cross-sections. In FIG. 2, the simulated structure is a PbS-CQD effective medium (400 nm)/MoO3 (50 nm)/Au (150 nm) with and without embedded Au nanoshell and the absorption was integrated within the PbS material only. The background index of refraction is matched to that of the PbS material to remove interference fringes in the absorption spectra.

### Example 13

### Plasmonic-Excitonic Solar Cell Fabrication

PbS CQD PV devices were fabricated on cleaned FTO-coated glass substrates (Pilkington, TEC 15). The n-type ZnO/TiO₂ electrode was made from a colloidal ZnO nanoparticle solution (Alfa Aesar Nanoshield ZN-2000) diluted to 25% in DI H₂O. FTO substrates were coated by spin-casting at 2000 r.p.m. and treated with a 120 mM TiCl₄ solution at 70 OC for 30 min. The substrates were then rinsed with de-ionized water and annealed on a hotplate at 520 OC for 45 min in air ambient. A layer-by-layer spin-casting process was used to build up the CQD film. Under an ambient atmosphere, 2 drops of PbS CQD were dropped through a 0.22 μm filter on the ZnO/TiO2 substrate, and spin-cast at 2500 r.p.m. A solid-state ligand exchange with mercaptopropionic acid (MPA) was done by flooding the surface for 3 sec, then spin-casting dry at 2500 r.p.m. Finally two washes with MeOH were used to remove unbound ligands. In the case of plasmonic particle deposition, nanorods were synthesized based on a seed-mediated growth method, and nanoshells were purchased from NanoComposix, Inc. Nanoshells in methanol solution were centrifuged at 1000 r.p.m. for 15 min and the centrifugation cycle was repeated twice. The final concentration of nanoshells dissolved in methanol was 30 mg ml₋₁. The solution was sonicated for 40 sec (42±3 kHz), and used immediately. Nanoshell solution (35 μl) was deposited on the PbS film on a level surface in a circular reservoir and allowed to dry under low vacuum (˜10₋₃ Torr) for 60 sec. Nanoshell deposition was done after 8 PbS layers, and was followed by 4 additional PbS layers. Each device (control and plasmonic) consisted of 12 total PbS layers. Top electrode deposition consisted of 10 nm thermally evaporated molybdenum trioxide deposited at a rate of 0.2 Å s₋₁, followed by electron-beam deposition of 50 nm of Au deposited at 1.5 Å s⁻¹, and finally 120 nm of thermally evaporated silver deposited at 3.0 Å s⁻¹.

### Example 14

### Absorption and Scattering Measurements

UV-Vis-NIR absorption and scattering spectra were taken in an integrating sphere for a drop-cast ensemble of nanorods or nanoshells on an ITO-coated glass substrate. Absorption curves were measured by tilting the sample at a slight angle relative to the illumination beam with all other ports closed so that all directly transmitted, reflected, and off-angle-scattered light was collected by the detector. Scattering curves were measured by orienting the sample normal to the incident beam with a port opposite the input port open so that only the off-angle-scattered light was detected. The 100% transmission baseline for both curves was measured with a bare ITO-coated glass substrate oriented at a slight angle relative to the illumination beam.

### Example 14

### AM1.5 Photovoltaic Device Characterization

PV and EQE device measurements were done under inert N₂-flow. Current-voltage measurements were done using a Keithley 2400 source meter with illumination from a solar simulator (Sciencetech, Class A, intensity=100 mW cm₋₂). The source intensity was measured with a Melles-Griot broadband power meter through a circular 0.049 cm₂ aperture. The spectral mismatch factor between the measured and actual solar spectrum was calculated to be 10%, thus a correction factor of 0.90 was applied to all current measurements. The uncertainty in the AM 1.5 characterization was estimated to be 7%.

### Example 15

### External Quantum Efficiency Measurements

External quantum efficiency measurements were obtained by applying chopped (220 kHz) monochromatic illumination (400 W xenon lamp through a monochromator with order-sorting filters) collimated and co-focused with a 1-sun intensity white-light source on the device of interest. The power was measured with calibrated Newport 818-UV and Newport 818-IR power meters. The response from the chopped signal was measured using a Stanford Research Systems lock-in amplifier at short-circuit conditions. The uncertainty in the EQE measurements was estimated to be ±8%.

Table 1 shows photovoltaic characteristics for an example photovoltaic device.

Table 2 shows average photovoltaic characteristics for example photovoltaic devices.

TABLE 1

| | Voc (V) | Jsc (mA/cm²) | FF (%) | PCE (%) |
|---|---|---|---|---|
| Control | 0.56 | 21.6 | 51.6 | 6.2 |
| Nanoshell | 0.58 | 24.5 | 49.6 | 6.9 |
| Percent change | +3.6 | +13.1 | −3.9 | +11.4 |

TABLE 2

| | | | St. Dev. | | | | |
|---|---|---|---|---|---|---|---|
| | | Jsc | in Jsc | | | St. Dev. | |
| | Voc (V) | (mA/cm²) | (mA/cm²) | FF (%) | PCE (%) | in PCE | # Devices |
| Control | 0.55 | 21.1 | 0.5 | 53.7 | 6.3 | 0.2 | 9 |
| Nanorod | 0.58 | 21.0 | 0.5 | 45.4 | 6.1 | 0.3 | 4 |
| Nanoshell | 0.57 | 23.2 | 0.6 | 51.3 | 6.6 | 0.2 | 9 |
| Percent | +5.7 | −0.6 | n/a | −15.5 | −2.6 | n/a | n/a |
| change | | | | | | | |
| (Nanorod- | | | | | | | |
| Control) | | | | | | | |
| Percent | +3.0 | +9.9 | n/a | −4.5 | +5.8 | n/a | n/a |
| change | | | | | | | |
| (Nanoshell- | | | | | | | |
| Control) | | | | | | | |

Although the forgoing invention has been described in some detail by way of illustration and example for clarity and understanding, it will be readily apparent to one of ordinary skill in the art in light of the teachings herein that certain variations, changes, modifications and substitutions of equivalents may be made thereto without necessarily departing from the spirit and scope of this invention. As a result, the embodiments described herein are subject to various modifications, changes and the like, with the scope of this invention being determined solely by reference to the claims appended hereto. Those of skill in the art will readily recognize a variety of non-critical parameters that could be changed, altered or modified to yield essentially similar results. In addition, each reference provided herein is incorporated by reference in its entirety to the same extent as if each reference was individually incorporated by reference. Where a conflict exists between the instant application and a reference provided herein, the instant application shall dominate.

What is claimed is:

1. An enhanced infrared (IR) light absorbing photovoltaic stack comprising:
a top electrode;
an absorbing layer (AL) comprising light-absorbing semiconductor nanoparticles (SNPs) that absorb at least a portion of the IR spectrum;
at least one plasmonic nanoparticle (PNP); and
a bottom electrode;
wherein the at least one PNP scatters incident IR light and thereby enhances IR absorption by the SNPs.

2. The photovoltaic stack of claim 1, wherein the AL is between and contacts the top electrode and the bottom electrode.

3. The photovoltaic stack of claim 1, wherein the top electrode is selected from the group consisting of Au, Ag, Pt, Pd, Ni, MoO₃, and combinations thereof.

4. The photovoltaic stack of claim 1, wherein the SNPs are selected from the group consisting of PbS, PbSe, CdS, CdSe, CdTe, PbTe, ZnS, ZnTe, ZnSe, and core-shell nanoparticles.

5. The photovoltaic stack of claim 1, wherein the SNPs comprise PbS colloidal quantum dots having a diameter from about 2 nm to about 10 nm.

6. The photovoltaic stack of claim 1, wherein the SNPs comprise PbS colloidal quantum dots having about the same sizes.

7. The photovoltaic stack of claim 1, further comprising halide ions bonded to the surface of the SNPs, wherein the halide ions are selected from the group consisting of fluoride, bromide, chloride, iodide, and combinations thereof.

8. The photovoltaic stack of claim 1, wherein the at least one PNP comprises:
a spherical dielectric core having an average diameter of about 25 nm to about 100 nm;
a metal shell surrounding the core and having an average thickness of about 2 nm to 50 nm; and
optionally an insulating shell surrounding the metal shell and having an average thickness of about 2 nm to 50 nm.

9. The photovoltaic stack of claim 8, wherein the dielectric core is selected from the group consisting of SiO₂, Si₃N₄, polystyrene, insulating polymers, and insulating metal oxides.

10. The photovoltaic stack of claim 8, wherein the metal shell is selected from the group consisting of Cu, Ag, Au, Pt, Pd, Ni, Al, and combinations thereof.

11. The photovoltaic stack of claim 8, wherein the core is SiO₂, the metal shell is Au, and the insulating shell is polyvinylpyrrolidone (PVP).

12. The photovoltaic stack of claim 1, wherein the at least one PNP is selected from the group consisting of:
a nanoparticle comprising:
a spherical dielectric core having an average diameter of about 25 nm to about 100 nm;
a metal shell surrounding the core and having an average thickness of about 2 nm to 50 nm; and
optionally an insulating shell surrounding the metal shell and having an average thickness of about 2 nm to 50 nm;
a nanorod having an average diameter of about 50 nm to about 70 nm and an average length of about 450 nm to about 550 nm; and
a nanosphere having an average diameter of about 100 nm to about 200 nm.

13. The photovoltaic stack of claim 1, wherein the at least one PNP is a nanorod or a nanosphere and comprises a metal selected from the group consisting of Cu, Ag, Au, Pt, and combinations thereof.

14. The photovoltaic stack of claim 1, wherein the at least one PNP is positioned about 50% to about 85% of the thickness of the stack from the top electrode.

15. The photovoltaic stack of claim 1, wherein the bottom electrode is selected from the group consisting of fluorine-doped tin oxide (FTO), indium-tin-oxide (ITO), TiO₂/FTO, ZnO/TiO₂/FTO, TiO₂/ITO, ZnO/TiO₂/ITO, and AZO (aluminum-doped Zinc Oxide)/FTO.

16. The photovoltaic stack of claim 1, wherein the bottom electrode comprises a depleted heterojunction (DHL) that contacts the AL.

17. The photovoltaic stack of claim 1, wherein the thickness of the AL is about 50 nm to about 500 nm.

18. The photovoltaic stack of claim 1, having about 2 to about 15 PNPs per μm².

19. The photovoltaic stack of claim 1, wherein the at least one PNP has a scattering-to-absorption ratio, S=σscattering/σabsorption, that is greater than 1 for wavelengths ranging from 400 nm to 1200 nm.

20. The photovoltaic stack of claim 1, wherein the at least one PNP has a localized surface plasmon resonance (LSPR) centered around a wavelength of 600, 650, 700, 750, 800, 850, 900, 950, or 1000 nm.
